(19) United States
(12) Patent Application Publication
(10) Pub. No.: US 2026/0276410 A1
(43) Pub. Date: Sep. 17, 2026

(54) MAGNETIC SENSOR SYSTEM AND POSITION DETECTION DEVICE

(71) Applicant: TDK CORPORATION, Tokyo (JP)

(72) Inventors: Tomoki HANADA, Tokyo (JP); Hiraku HIRABAYASHI, Tokyo (JP)

(73) Assignee: TDK CORPORATION, Tokyo (JP)

(21) Appl. No.: 19/561,735

(22) Filed: Mar. 10, 2026

Related U.S. Application Data
(60) Provisional application No. 63/770,004, filed on Mar. 11, 2025.

(51) Int. Cl. G01D 5/14; G01D 5/16

(52) U.S. Cl. CPC G01D 5/145; G01D 5/16

(57) ABSTRACT

A magnetic sensor system includes: magnetic field generator including first and second part aligned in first direction; magnetic sensor configured to detect magnetic field generated by magnetic field generator at detection position. Magnetic field generator and magnetic sensor are configured such that relative position of magnetic field generator with respect to magnetic sensor changes in direction parallel to first direction. Magnetic sensor is configured to generate first and second detection signal that change in response to relative position and have phases different from each other, based on magnetic field. Magnetic field generator is configured such that distance between first position where first detection signal is a maximum value and second position where second detection signal is a maximum value is smaller than distance between center of first part and center of second part in first direction.

### CROSS REFERENCE TO RELATED APPLICATIONS

This application claims the benefit of U.S. Provisional Patent Application No. 63/770,004 filed on Mar. 11, 2025, the entire contents of which are incorporated herein by reference.

### BACKGROUND

The disclosure relates to a magnetic sensor system and a position detection device.

Position detection devices using a magnetic sensor have been used for various applications in recent years. The position detection devices using the magnetic sensor will hereinafter be referred to as magnetic position detection devices. The magnetic position detection device is used, for example in a camera module that is built into a smartphone and includes an optical image stabilization mechanism or an autofocus mechanism, to detect the position of the lens.

The magnetic position detection device includes, for example, a magnet that moves in conjunction with movement of a target object, and a magnetic sensor that detects a magnetic field generated by the magnet.

Japanese Patent Application Laid-Open Publication No. 2016-133371 (JP2016-133371A) discloses a magnetic position detection device that detects a position using a Hall element that moves relative to a magnet. The magnet is configured such that the distance between a surface of the magnet facing the Hall element and the Hall element changes in a direction of the relative movement.

Japanese Patent Application Laid-Open Publication No. 2001-050703 (JP2001-050703A) discloses a magnetic displacement detection device including a magnet and a Hall element. The magnet is formed such that the distance between the magnet and the Hall element is smallest near the center of the magnet and larger at an end portion of the magnet than near the center of the magnet.

Japanese Patent Application Laid-Open Publication No. 2009-276230 (JP2009-276230A) discloses a stroke sensor having a Hall IC mounted thereon to detect a magnetic flux density emitted from a sensor magnet that moves together with an output rod. The sensor magnet has opposing surfaces facing a detection surface of the Hall IC formed as circular arc surfaces with the same radius of curvature in a front-to-back direction.

### SUMMARY

A magnetic sensor system according to one embodiment of the disclosure includes a magnetic field generator including a first part and a second part aligned in a first direction, the first part being magnetized to include a magnetization component in a second direction orthogonal to the first direction, the second part being magnetized to include a magnetization component in a third direction opposite to the second direction; and a magnetic sensor configured to detect a magnetic field generated by the magnetic field generator at a detection position. The magnetic field generator and the magnetic sensor are configured such that a relative position, which is a relative position of the magnetic field generator with respect to the magnetic sensor, changes in a direction parallel to the first direction. The magnetic sensor is configured to generate a first detection signal and a second detection signal whose phases differ from each other in response to the relative position, based on the magnetic field. The first detection signal is a maximum value when the relative position is a first position. The second detection signal is a maximum value when the relative position is a second position. The magnetic field generator is configured such that a distance between the first position and the second position is smaller than a distance between a center of the first part in the first direction and a center of the second part in the first direction.

A position detection device according to one embodiment of the disclosure includes: the magnetic sensor system according to one embodiment of the disclosure; and a target object whose position is variable. The magnetic field generator, the magnetic sensor, and the target object are configured such that the relative position changes when a position of the target object changes.

Objects, features, and advantages of the disclosure will appear more fully from the following description.

### BRIEF DESCRIPTION OF THE DRAWINGS

The accompanying drawings are included to provide a further understanding of the disclosure and are incorporated in and constitute a part of this specification. The drawings illustrate example embodiments and, together with the specification, serve to explain the principles of the technology.

FIG. 1 is a perspective view showing a camera module including a magnetic sensor system according to a first example embodiment of the disclosure.

FIG. 2 is an explanatory diagram schematically showing an inside of the camera module shown in FIG. 1.

FIG. 3 is a side view showing the magnetic sensor system according to the first example embodiment of the disclosure.

FIG. 4 is a plan view showing the magnetic sensor system according to the first example embodiment of the disclosure.

FIG. 5 is a plan view showing a first example of a magnetic sensor in the first example embodiment of the disclosure.

FIG. 6 is a plan view showing a second example of the magnetic sensor in the first example embodiment of the disclosure.

FIG. 7 is a circuit diagram showing a circuit configuration of the magnetic sensor in the first example embodiment of the disclosure.

FIG. 8 is a perspective view showing a magnetoresistive element and a slope structure in the first example embodiment of the disclosure.

FIG. 9 is an explanatory diagram for describing a first magnetoresistive element in the first example embodiment of the disclosure.

FIG. 10 is an explanatory diagram for describing a second magnetoresistive element in the first example embodiment of the disclosure.

FIG. 11 is an explanatory diagram for describing a third magnetoresistive element in the first example embodiment of the disclosure.

FIG. 12 is an explanatory diagram for describing a fourth magnetoresistive element in the first example embodiment of the disclosure.

FIG. 13 is a plan view showing a plurality of magnetoresistive elements and a plurality of slope structures in the first example embodiment of the disclosure.

FIG. 14 is a perspective view showing a magnetic field generator of a comparative example.

FIG. 15 is a side view showing a magnetic sensor system of the comparative example.

FIG. 16 is an image showing a distribution of strengths of a first magnetic field of the comparative example.

FIG. 17 is an image showing a distribution of strengths of a first magnetic field in the first example embodiment of the disclosure.

FIG. 18 is an image showing a distribution of strengths of a second magnetic field of the comparative example.

FIG. 19 is an image showing a distribution of strengths of a second magnetic field in the first example embodiment of the disclosure.

FIG. 20 is an image showing a distribution of strengths of a third magnetic field of the comparative example.

FIG. 21 is an image showing a distribution of strengths of a third magnetic field in the first example embodiment of the disclosure.

FIG. 22 is an image showing a distribution of directions of a magnetic field generated by the magnetic field generator of the comparative example.

FIG. 23 is an image showing a distribution of directions of a magnetic field generated by the magnetic field generator in the first example embodiment of the disclosure.

FIG. 24 is a waveform chart showing detection signals of the magnetic sensor of the comparative example and the magnetic sensor in the first example embodiment of the disclosure.

FIG. 25 is a characteristic diagram showing a magnetic field angle of the comparative example and a magnetic field angle in the first example embodiment of the disclosure.

FIG. 26 is a characteristic diagram showing errors in the magnetic field angle of the comparative example.

FIG. 27 is a characteristic diagram showing errors in the magnetic field angle in the first example embodiment of the disclosure.

FIG. 28 is a characteristic diagram showing a detection value of the comparative example and a detection value in the first example embodiment of the disclosure.

FIG. 29 is a side view showing the magnetic field generator and an imaginary substrate of the comparative example.

FIG. 30 is a side view showing the magnetic field generator and an imaginary substrate in the first example embodiment of the disclosure.

FIG. 31 is an image showing a distribution of the strengths of the first magnetic field in the imaginary substrate of the comparative example.

FIG. 32 is an image showing a distribution of the strengths of the first magnetic field in the imaginary substrate in the first example embodiment of the disclosure.

FIG. 33 is an image showing a distribution of the strengths of the second magnetic field in the imaginary substrate of the comparative example.

FIG. 34 is an image showing a distribution of the strengths of the second magnetic field in the imaginary substrate in the first example embodiment of the disclosure.

FIG. 35 is an image showing a distribution of the strengths of the third magnetic field in the imaginary substrate of the comparative example.

FIG. 36 is an image showing a distribution of the strengths of the third magnetic field in the imaginary substrate in the first example embodiment of the disclosure.

FIG. 37 is a characteristic diagram showing a magnitude of the first magnetic field shown in FIG. 31 and FIG. 32 and a magnitude of the third magnetic field shown in FIG. 35 and FIG. 36.

FIG. 38 is a characteristic diagram showing a magnitude of the first magnetic field shown in FIG. 16 and FIG. 17 and a magnitude of the third magnetic field shown in FIG. 20 and FIG. 21.

FIG. 39 is a side view showing a first modification example of the magnetic field generator according to the first example embodiment of the disclosure.

FIG. 40 is a side view showing a second modification example of the magnetic field generator according to the first example embodiment of the disclosure.

FIG. 41 is a perspective view showing a part of a resistor section of one of first and second detection circuits in a second example embodiment of the disclosure.

FIG. 42 is a perspective view showing a magnetoresistive element in the second example embodiment of the disclosure.

FIG. 43 is a perspective view showing a part of the second detection circuit in the second example embodiment of the disclosure.

FIG. 44 is a plan view showing a part of the second detection circuit in the second example embodiment of the disclosure.

FIG. 45 is a side view showing a part of the second detection circuit in the second example embodiment of the disclosure.

FIG. 46 is a plan view showing a part of a magnetic sensor in a third example embodiment of the disclosure.

FIG. 47 is a cross-sectional view showing a part of the magnetic sensor in the third example embodiment of the disclosure.

### DETAILED DESCRIPTION

One object of the disclosure is to provide a magnetic sensor system and a position detection device that are capable of improving a detection accuracy even when a movable range of a magnetic sensor or a magnetic field generator is relatively narrow in the magnetic sensor system configured such that a relative position of the magnetic field generator with respect to the magnetic sensor changes.

In the following, some example embodiments and modification examples of the disclosure are described in detail with reference to the accompanying drawings. Note that the following description is directed to illustrative examples of the disclosure and not to be construed as limiting the technology. Factors including, without limitation, numerical values, shapes, materials, components, positions of the components, and how the components are coupled to each other are illustrative only and not to be construed as limiting the technology. Further, elements in the following example embodiments which are not recited in a most-generic independent claim of the disclosure are optional and may be provided on an as-needed basis. The drawings are schematic and are not intended to be drawn to scale. Like elements are denoted with the same reference numerals to avoid redundant descriptions.

### First Example Embodiment

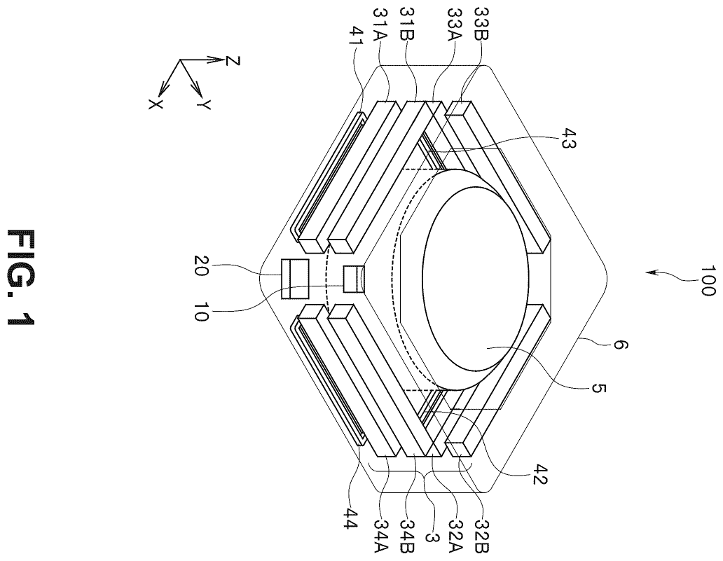

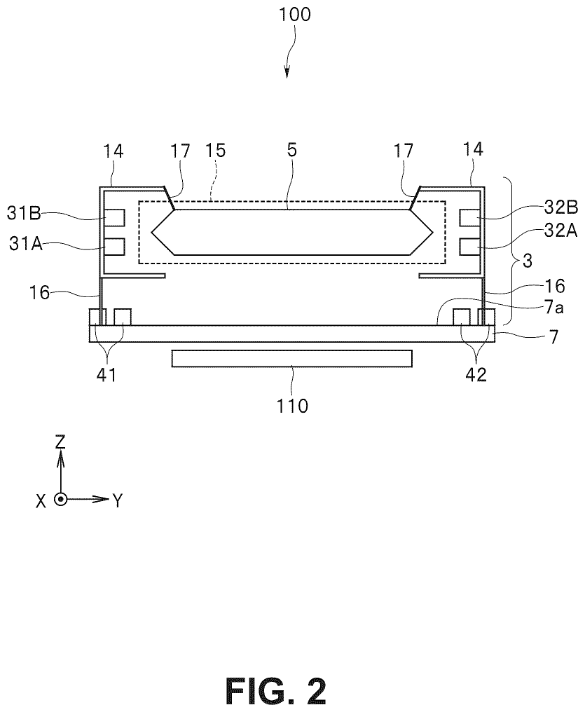

First, a configuration of a camera module 100 including a magnetic sensor system according to a first example embodiment of the disclosure will be described with reference to FIG. 1 and FIG. 2. FIG. 1 is a perspective view showing the camera module 100. FIG. 2 is an explanatory diagram schematically showing an inside of the camera module 100. Note that in FIG. 2, for ease of understanding, the components of the camera module 100 are depicted with dimensions and arrangements different from those in FIG. 1. The camera module 100 according to the example embodiment constitutes a part of a camera for a smartphone including an optical image stabilization mechanism and an autofocus mechanism, for example, and is used in combination with an image sensor 110 using a CMOS, or the like.

The camera module 100 in the example embodiment includes a driving device 3, a lens 5, a case 6, and a substrate 7. The driving device 3 changes a relative position of the lens 5 with respect to the image sensor 110. In particular in the example embodiment, the driving device 3 is configured to move the lens 5. The case 6 protects the driving device 3. The substrate 7 has a top surface 7a. Note that the substrate 7 is omitted in FIG. 1, and the case 6 is omitted in FIG. 2.

The driving device 3 includes the magnetic sensor system according to the example embodiment. The magnetic sensor system constitutes a position detection device according to the example embodiment, together with a target object whose position is variable. In the example embodiment, the target object is the lens 5. The magnetic sensor system and the position detection device will be described later.

Here, as shown in FIG. 1 and FIG. 2, an X direction, a Y direction, and a Z direction are defined. The X, Y, and Z directions are orthogonal to one another. In the example embodiment, a direction that is perpendicular to the top surface 7a of the substrate 7 (the upward direction in FIG. 2) is referred to as the Z direction. Each of the X direction and the Y direction is a direction parallel to the top surface 7a of the substrate 7. In addition, opposite directions to the X, Y, and Z directions are referred to as −X, −Y, and −Z directions, respectively. In addition, a direction parallel to the X direction and −X direction is referred to as an X-axis direction, a direction parallel to the Y direction and the −Y direction is referred to as a Y-axis direction, and a direction parallel to the Z direction and the −Z direction is referred to as a Z-axis direction.

Hereinafter, a position located forward of a reference position in the Z direction is referred to as “above”, and a position opposite from the “above” position with respect to the reference position is referred to as “below”. Furthermore, the shape of each component of the camera module 100 in planar view from the Z direction is referred to as “planar shape”.

The lens 5 is disposed above the top surface 7a of the substrate 7 in an orientation such that an optical axis direction of the lens 5 coincides with the Z-axis direction. In addition, the substrate 7 includes an opening (not shown) through which light passing through the lens 5 is transmitted. As shown in FIG. 2, the camera module 100 is aligned with respect to the image sensor 110 such that light passing through the lens 5 and the opening (not shown) is incident onto the image sensor 110.

The driving device 3 includes a first holding member 14, a second holding member 15, a plurality of first wires 16, and a plurality of second wires 17. The second holding member 15 holds the lens 5. Although not shown in the figures, the second holding member 15 has, for example, a cylindrical shape configured to allow the lens 5 to be mounted inside thereof.

The second holding member 15 is provided such that its position can be changed in one direction with respect to the first holding member 14, in particular, in the Z-axis direction, which is the optical axis direction of the lens 5. In the example embodiment, the first holding member 14 has a box-like shape configured to accommodate both the lens 5 and the second holding member 15 inside thereof. The plurality of second wires 17 connect the first holding member 14 and the second holding member 15, and support the second holding member 15 such that the second holding member 15 can move with respect to the first holding member 14 in the Z-axis direction.

The first holding member 14 is provided above the top surface 7a of the substrate 7 such that its position can be changed with respect to the substrate 7 in the X-axis direction and the Y-axis direction. The plurality of first wires 16 connect the substrate 7 and the first holding member 14, and support the first holding member 14 such that the first holding member 14 can move with respect to the substrate 7 in the X-axis direction and the Y-axis direction. When the relative position of the first holding member 14 with respect to the substrate 7 changes, the relative position of the second holding member 15 with respect to the substrate 7 also changes.

The driving device 3 further includes magnets 31A, 31B, 32A, 32B, 33A, 33B, 34A, and 34B, and coils 41, 42, 43, and 44. The magnet 31A is disposed forward of the lens 5 in the −Y direction. The magnet 32A is disposed forward of the lens 5 in the Y direction. The magnet 33A is disposed forward of the lens 5 in the −X direction. The magnet 34A is disposed forward of the lens 5 in the X direction. The magnets 31B, 32B, 33B, and 34B are disposed above the magnets 31A, 32A, 33A, and 34A, respectively. In addition, the magnets 31A, 31B, 32A, 32B, 33A, 33B, 34A, and 34B are fixed to the first holding member 14.

As shown in FIG. 1, the magnets 31A, 31B, 32A, and 32B each have a rectangular parallelepiped shape long in the X-axis direction. The magnets 33A, 33B, 34A, and 34B each have a rectangular parallelepiped shape long in the Y-axis direction.

The coil 41 is disposed between the magnet 31A and the substrate 7. The coil 42 is disposed between the magnet 32A and the substrate 7. The coil 43 is disposed between the magnet 33A and the substrate 7. The coil 44 is disposed between the magnet 34A and the substrate 7. In addition, the coils 41, 42, 43, and 44 are fixed to the substrate 7.

The driving device 3 further includes two other coils (not shown). The two other coils are, for example, disposed between the magnets 31A and 31B and the lens 5 and between the magnets 32A and 32B and the lens 5, respectively. The two other coils (not shown) are fixed to the second holding member 15.

The coil 41 is mainly subjected to a magnetic field generated by the magnet 31A. The coil 42 is mainly subjected to a magnetic field generated by the magnet 32A. The coil 43 is mainly subjected to a magnetic field generated by the magnet 33A. The coil 44 is mainly subjected to a magnetic field generated by the magnet 34A.

The driving device 3 further includes a magnetic sensor 40 fixed to the substrate 7 near one of the coils 41 and 42, and a magnetic sensor 40 fixed to the substrate 7 near one of the coils 43 and 44. Here, the two magnetic sensors 40 are assumed to be disposed near the coil 41 and the coil 44, respectively. As will be described later, the two magnetic sensors 40 are used when the position of the lens 5 is changed to reduce the effects of hand-induced camera shake.

The magnetic sensor 40 disposed near the coil 41 detects the magnetic field generated by the magnet 31A, and generates a detection value corresponding to the position of the magnet 31A. The magnetic sensor 40 disposed near the coil 44 detects the magnetic field generated by the magnet 34A, and generates a detection value corresponding to the position of the magnet 34A. A configuration of the magnetic sensor 40 will be described later.

The driving device 3 further includes a magnet 10 and a magnetic sensor 20. The magnetic sensor 20 is used to detect the position of the lens 5 when automatic focusing is performed. The magnetic sensor 20 is fixed to the substrate 7 near an end portion of the magnet 31A in the X direction and an end portion of the magnet 34A in the −Y direction. The magnetic sensor 20 is configured, for example, by elements that detect the magnetic field, such as Hall elements or magnetoresistive elements.

The magnet 10 is fixed to the second holding member 15 above the magnetic sensor 20. When the relative position of the second holding member 15 with respect to the first holding member 14 changes in the Z-axis direction, the relative position of the magnet 10 with respect to the first holding member 14 also changes in the Z-axis direction.

Here, an operation of the driving device 3 will be described. First, an optical image stabilization mechanism and an autofocus mechanism will be briefly described. The driving device 3 constitutes part of the optical image stabilization mechanism and the autofocus mechanism. The driving device 3, the optical image stabilization mechanism, and the autofocus mechanism are controlled by a control section (not shown) external to the camera module 100.

The optical image stabilization mechanism is configured to detect hand-induced camera shake, for example, using an accelerometer or a gyro sensor external to the camera module 100. When the optical image stabilization mechanism detects the hand-induced camera shake, the control section (not shown) controls the driving device 3 such that the relative position of the lens 5 with respect to the substrate 7 changes according to patterns of the hand-induced camera shake. This stabilizes the absolute position of the lens 5, thereby reducing the effect of the hand-induced camera shake. Note that the relative position of the lens 5 with respect to the substrate 7 changes in the X-axis direction or the Y-axis direction according to the patterns of the hand-induced camera shake.

The autofocus mechanism is configured, for example, to be capable of detecting a state where focus is achieved on a subject by the image sensor 110, an autofocus sensor, or the like. The control section (not shown) changes the relative position of the lens 5 with respect to the substrate 7 in the Z-axis direction via the driving device 3 to achieve focus on the subject. This enables automatic focusing on the subject.

Next, an operation of the driving device 3 related to the optical image stabilization mechanism will be described. When current is caused to flow through the coils 41 and 42 via the control section (not shown), the interaction between the magnetic field generated by the magnets 31A and 32A and the magnetic field generated by the coils 41 and 42 causes the first holding member 14, to which the magnets 31A and 32A are fixed, to move in the Y-axis direction. As a result, the lens 5 also moves in the Y-axis direction. In addition, when current is caused to flow through the coils 43 and 44 via the control section (not shown), the interaction between the magnetic field generated by the magnets 33A and 34A and the magnetic field generated by the coils 43 and 44 causes the first holding member 14, to which the magnets 33A and 34A are fixed, to move in the X-axis direction. As a result, the lens 5 also moves in the X-axis direction. The control section (not shown) detects the position of the lens 5 by measuring signals that correspond to the positions of the magnets 31A and 34A and are generated by the two magnetic sensors 40.

Next, an operation of the driving device 3 related to the autofocus mechanism will be described. When the relative position of the lens 5 with respect to the substrate 7 is moved in the Z direction, the control section (not shown) causes a Lorentz force in the Z direction to be applied to the two other coils (not shown) by the current flowing through the two other coils (not shown) respectively and the magnetic fields generated by the magnets 31A, 31B, 32A, and 32B. Consequently, the second holding member 15, to which the two other coils (not shown) are fixed, moves in the Z direction. As a result, the lens 5 also moves in the Z direction.

When the relative position of the lens 5 with respect to the substrate 7 is moved in the −Z direction, the control section (not shown) causes current to flow through the two other coils (not shown) in the opposite direction to that when moved in the Z direction.

When the relative position of the lens 5 with respect to the substrate 7 changes in the Z-axis direction, the relative position of the magnet 10 with respect to the magnetic sensor 20 also changes in the Z-axis direction. The magnetic sensor 20 detects at least the magnetic field generated by the magnet 10, and generates the signal corresponding to the position of the magnet 10.

The magnetic sensor 20 may detect a composite magnetic field of the magnetic field generated by the magnet 10, the magnetic field generated by the magnet 31A, and the magnetic field generated by the magnet 34A. The direction of the composite magnetic field may change within a plane parallel to the top surface 7a of the substrate 7. At least one of the direction or the magnitude of the composite magnetic field changes in response to the relative position of the lens 5 with respect to the substrate 7.

Next, a schematic configuration of the magnetic sensor system according to the example embodiment will be described. A magnetic sensor system 120 according to the example embodiment includes a magnetic field generator configured to generate a target magnetic field, and a magnetic sensor configured to detect the target magnetic field at a detection position. In the example embodiment, the magnetic sensor 40 disposed near the coil 41 or the magnetic sensor 40 disposed near the coil 44 corresponds to the magnetic sensor in the example embodiment. In the magnetic sensor system including the magnetic sensor 40 disposed near the coil 41, the magnet 31A corresponds to the magnetic field generator in the example embodiment. In the magnetic sensor system including the magnetic sensor 40 disposed near the coil 44, the magnet 34A corresponds to the magnetic field generator in the example embodiment. In the following description, the magnetic field generator constituting a magnetic sensor system 120 is represented by the reference sign 30.

The position detection device according to the example embodiment includes the magnetic sensor system 120 and the target object whose position is variable, and is configured to detect the position of the target object. In particular in the example embodiment, the target object is the lens 5.

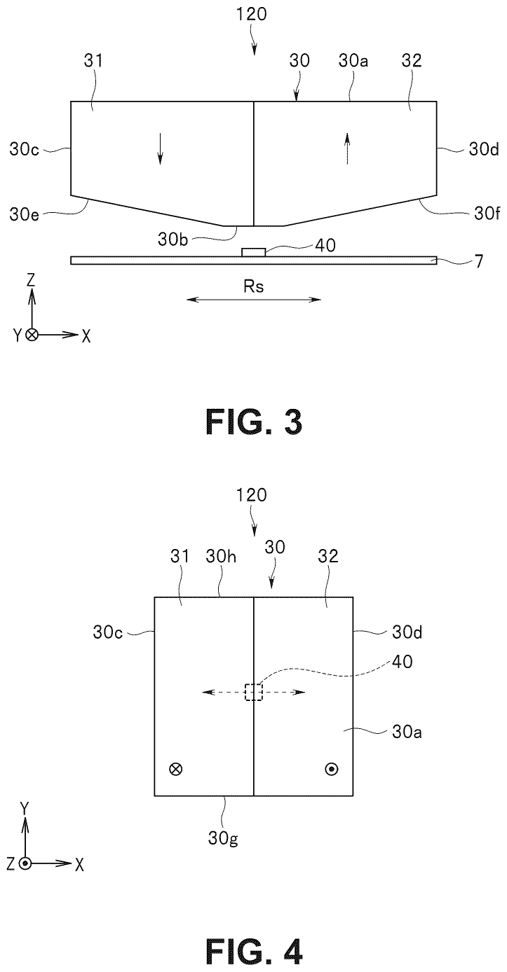

Next, with reference to FIG. 3 and FIG. 4, the magnetic sensor system 120 including the magnetic field generator 30 and the magnetic sensor 40 will be described. FIG. 3 is a side view showing the magnetic sensor system 120. FIG. 4 is a plan view showing the magnetic sensor system 120.

Here, as shown in FIG. 3 and FIG. 4, an X direction, a Y direction, and a Z direction are defined. The Z direction shown in FIG. 3 and FIG. 4 coincides with the Z direction shown in FIG. 1 and FIG. 2. The X direction and the Y direction shown in FIG. 3 and FIG. 4 may coincide or may not coincide with the X direction and the Y direction shown in FIG. 1 and FIG. 2.

The magnetic field generator 30 and the magnetic sensor 40 are aligned in the Z direction. In the example shown in FIG. 3, the magnetic field generator 30 is arranged on the side of the Z direction with respect to the magnetic sensor 40. The detection position may be a position where the magnetic sensor 40 is disposed, for example. In planar view from the Z direction, the position where the magnetic sensor 40 is disposed, which is the detection position, is a position overlapping the magnetic field generator 30 and is a position separate from both ends of the magnetic field generator 30 in the Y-axis direction.

The magnetic field generator 30 and the magnetic sensor 40 are configured such that the relative position of the magnetic field generator 30 with respect to the magnetic sensor 40 changes in the X-axis direction. As described above, the magnetic sensor 40 is fixed to the substrate 7, and the magnetic field generator 30, which is the magnet 31A and the magnet 34A, is fixed to the first holding member 14 (see FIG. 2). When the position of the first holding member 14 with respect to the substrate 7 changes in the X-axis direction, the relative position of the magnetic field generator 30 with respect to the magnetic sensor 40 also changes in the X-axis direction. The detection value of the magnetic sensor 40 corresponds to the relative position of the magnetic field generator 30 with respect to the magnetic sensor 40 in the X-axis direction. Hereinafter, the relative position of the magnetic field generator 30 with respect to the magnetic sensor 40 in the X-axis direction is simply referred to as a relative position. The magnetic field generator 30, the magnetic sensor 40, and the target object are configured such that the relative position changes when the position of the target object changes.

The arrow labeled the symbol Rs in FIG. 3 and the dashed arrow in FIG. 4 represent a movable range Rs of the magnetic sensor 40 in planar view from the magnetic field generator 30 and a moving direction of the magnetic sensor 40 when seen from the magnetic field generator 30. The movable range Rs may be smaller than the dimension of the magnetic field generator 30 in the X-axis direction. When the magnetic field generator 30 or the magnetic sensor 40 is located at the center of the movable range Rs, the magnetic sensor 40 may overlap the center of gravity of the planar shape of the magnetic field generator 30 in planar view from the Z direction.

The magnetic field generator 30 includes two parts 31 and 32. The two parts 31 and 32 are arranged in this order in the X direction. The part 31 is magnetized to include a magnetization component in the −Z direction. The part 32 is magnetized to include a magnetization component in the Z direction. In FIG. 3, the arrow drawn to overlap the part 31 represents the direction of the magnetization of the part 31, and the arrow drawn to overlap the part 32 represents the direction of the magnetization of the part 32.

The magnetic field generator 30 has a three-dimensional shape formed by chamfering, among a plurality of corners of a rectangular parallelepiped, the corners located at the end in the −Z direction and at the end in the −X direction and the corners located at the end in the −Z direction and at the end in the X direction. The magnetic field generator 30 has a top surface 30a, which is a first surface, located at the end in the Z direction, a bottom surface 30b, which is a second surface, located at the end in the −Z direction, a first side surface 30c located at the end in the −X direction, a second side surface 30d located at the end in the X direction, a first connection surface 30e connecting the bottom surface 30b and the first side surface 30c, a second connection surface 30f connecting the bottom surface 30b and the second side surface 30d, a side surface 30g located at the end in the −Y direction, and a side surface 30h located at the end in the Y direction. At least a part of each of the top surface 30a and the bottom surface 30b may be a surface parallel to an XY plane orthogonal to the Z direction. At least a part of each of the first side surface 30c and the second side surface 30d may be a surface parallel to a YZ plane orthogonal to the X direction. At least a part of each of the side surfaces 30g and 30h may be a surface parallel to an XZ plane orthogonal to the Y direction.

The dimension of the first side surface 30c in the Z-axis direction and the dimension of the second side surface 30d in the Z-axis direction are smaller than the distance between the top surface 30a and the bottom surface 30b in the Z-axis direction. Therefore, the dimension of the magnetic field generator 30 in the Z-axis direction becomes small at a part near the first side surface 30c and a part near the second side surface 30d, and becomes large at a center part in the X-axis direction. In addition, the dimension of the first connection surface 30e in the Z-axis direction may be smaller than the dimension of the first side surface 30c in the Z-axis direction. The dimension of the second connection surface 30f in the Z-axis direction may be smaller than the dimension of the second side surface 30d in the Z-axis direction.

The first connection surface 30e may be a surface inclined with respect to the XY plane and the YZ plane, respectively, such that the distance between the first connection surface 30e and the top surface 30a in the Z-axis direction becomes smaller as the first connection surface 30e approaches the first side surface 30c. The second connection surface 30f may be a surface inclined with respect to the XY plane and the YZ plane, respectively, such that the distance between the second connection surface 30f and the top surface 30a in the Z-axis direction becomes smaller as the second connection surface 30f approaches the second side surface 30d. In addition, each of the first connection surface 30e and the second connection surface 30f may be a surface perpendicular to the XZ plane.

Each of the first connection surface 30e and the second connection surface 30f may have a plane, may have a curved surface, or may have a plane and a curved surface. When at least part of each of the first connection surface 30e and the second connection surface 30f is a curved surface, the curved surface may be a protruding surface protruding outward from the magnetic field generator 30 or a recessed surface recessed toward the inside of the magnetic field generator 30.

The bottom surface 30b may include the boundary between the part 31 and the part 32. The first connection surface 30e and the second connection surface 30f do not have to have the boundary between the part 31 and the part 32.

A magnetic field generated by the magnetic field generator 30 includes, in a space adjacent to the magnetic field generator 30, a component perpendicular to the top surface 30a, a component perpendicular to the bottom surface 30b, a component perpendicular to the first connection surface 30e, and a component perpendicular to the second connection surface 30f. Focusing on a space adjacent to the parts 31 and 32, the magnetic field generated by the magnetic field generator 30 includes, in this space, a component in the Z direction, a component in the −Z direction, a component perpendicular to the first connection surface 30e, which is inclined with respect to the Z-axis direction, and a component perpendicular to the second connection surface 30f, which is inclined with respect to the Z-axis direction.

The target magnetic field at the detection position is a part of the magnetic field generated by the magnetic field generator 30. In an imaginary plane including the detection position and parallel to the XY plane, the target magnetic field includes a magnetic field component Bx which is a component in the X-axis direction, a magnetic field component By which is a component in the Y-axis direction, and a magnetic field component Bz which is a component in the Z-axis direction. The magnetic field generator 30 and the magnetic sensor 40 are configured such that the magnetic field components Bx and Bz at the detection position change when the relative position changes.

Furthermore, the magnetic field generator 30 and the magnetic sensor 40 may be configured such that the magnitude of the magnetic field component By at the detection position is zero or nearly zero. Specifically, the magnetic sensor 40 may be arranged such that, when the relative position changes, the magnitude of each of the magnetic field components Bx and Bz at the detection position changes, but the magnitude of the magnetic field component By does not change or remains almost unchanged. In this case, the direction of the target magnetic field at the detection position changes in the XZ plane including the detection position. Hereinafter, the direction of the target magnetic field refers to the direction of the target magnetic field at the detection position and the direction of the target magnetic field which changes in the XZ plane including the detection position.

The magnetic field component Bx may be directed in the X direction or the −X direction at the center of a variable range of the relative position, for example. The magnetic field component Bz may be directed in one of the Z direction or the −Z direction at one end of the variable range and directed in another of the Z direction or the −Z direction at another end of the variable range. The magnetic field components Bx, By, and Bz will be described in detail later.

Next, the configuration of the magnetic sensor 40 will be described. First, an overview of the magnetic sensor 40 will be described. The magnetic sensor 40 is configured to detect the target magnetic field at the detection position. Note that the magnetic sensor 40 may be configured to detect both of the magnetic field component Bx and the magnetic field component Bz at the detection position. Alternatively, the magnetic sensor 40 may be configured to detect one of the magnetic field component Bx and the magnetic field component Bz. In addition, the magnetic sensor 40 may be configured to generate two detection signals whose phases differ by 90° electrical angle from each other in response to the change in the relative position. Each of the two detection signals changes periodically in response to the change in the relative position. Furthermore, when the relative position changes, the direction of the target magnetic field changes. Therefore, each of the two detection signals has a correspondence with the direction of the target magnetic field.

Hereinafter, one of the two detection signals is also referred to as a cosine signal, and the other of the two detection signals is also referred to as a sine signal. The cosine signal and the sine signal each have a correspondence with the direction of the target magnetic field. Both of the cosine signal and the sine signal may have correspondences with the magnitude of the magnetic field component Bx and the magnitude of the magnetic field component Bz. Alternatively, one of the cosine signal and the sine signal may have a correspondence with the magnitude of the magnetic field component Bx, and the other of the cosine signal and the sine signal may have a correspondence with the magnitude of the magnetic field component Bz. Alternatively, both of the cosine signal and the sine signal may have a correspondence with one of the magnitude of the magnetic field component Bx or the magnitude of the magnetic field component Bz, and do not have to have a correspondence with the other.

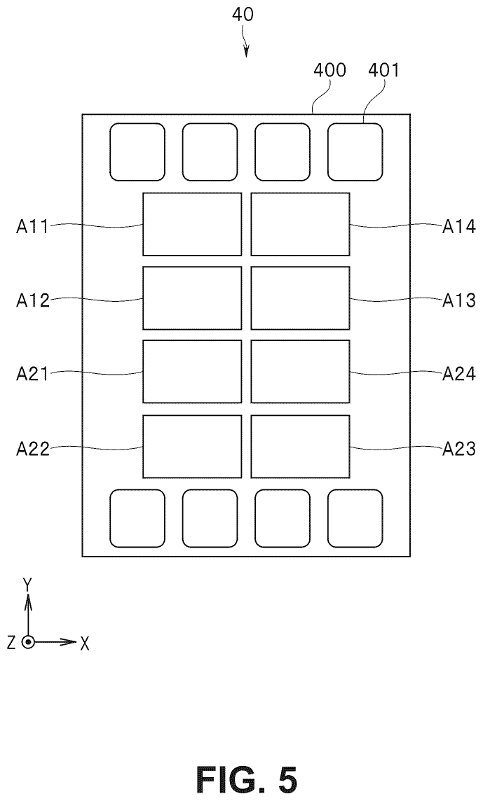

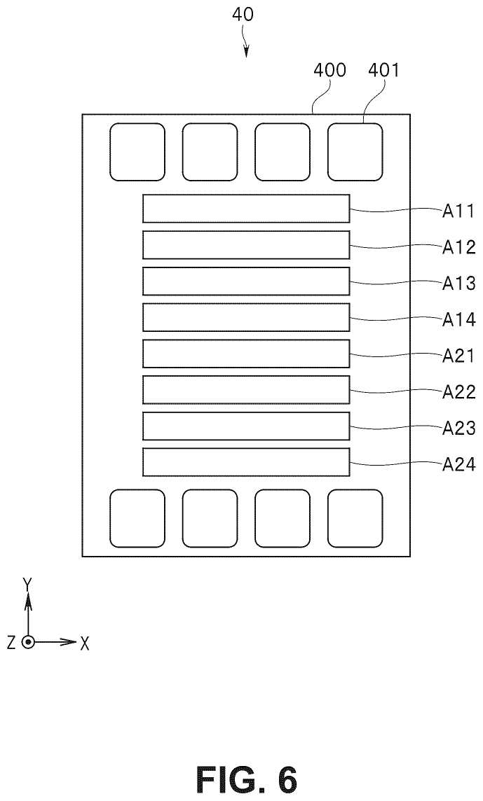

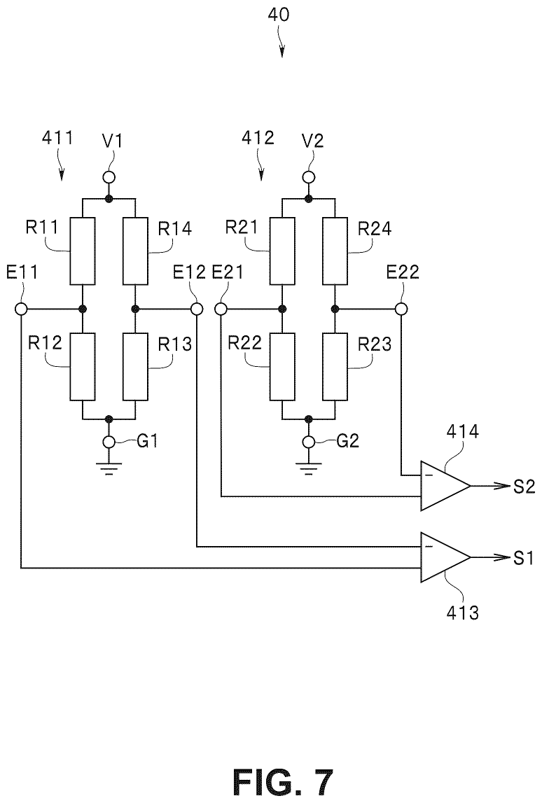

Next, with reference to FIG. 5, FIG. 6, and FIG. 7, the magnetic sensor 40 configured to generate a first detection signal S1 as the cosine signal and a second detection signal S2 as the sine signal will be described. FIG. 5 is a plan view showing a first example of the magnetic sensor 40. FIG. 6 is a plan view showing a second example of the magnetic sensor 40. FIG. 7 is a circuit diagram showing a circuit configuration of the magnetic sensor 40.

As shown in FIG. 7, the magnetic sensor 40 includes a first bridge circuit 411, which is a first detection circuit configured to generate the first detection signal S1 as the cosine signal, and a second bridge circuit 412, which is a second detection circuit configured to generate the second detection signal S2 as the sine signal. The first bridge circuit 411 is also referred to as a cosine bridge. The second bridge circuit 412 is also referred to as a sine bridge.

Each of the first bridge circuit 411 and the second bridge circuit 412 includes a plurality of magnetic detection elements. In addition, each of the first bridge circuit 411 and the second bridge circuit 412 includes a plurality of resistor sections including at least one magnetic detection element of the plurality of magnetic detection elements. The magnetic detection element may be a magnetoresistive element or a Hall element. The magnetoresistive element may be an anisotropic magnetoresistive (AMR) element utilizing the anisotropic magnetoresistive effect, a giant magnetoresistive (GMR) element utilizing the giant magnetoresistive effect, or a tunnel magnetoresistive (TMR) element utilizing the tunnel magnetoresistive effect.

The first bridge circuit 411 includes a power supply port V1, a ground port G1, two output ports E11 and E12, and four resistor sections R11, R12, R13, and R14. The resistor section R11 is provided between the power supply port V1 and the output port E11. The resistor section R12 is provided between the ground port G1 and the output port E11. The resistor section R13 is provided between the ground port G1 and the output port E12. The resistor section R14 is provided between the power supply port V1 and the output port E12.

A voltage or current of a specific magnitude is applied to the power supply port V1. The ground port G1 is connected to the ground.

The second bridge circuit 412 includes a power supply port V2, a ground port G2, two output ports E21 and E22, and four resistor sections R21, R22, R23, and R24. The resistor section R21 is provided between the power supply port V2 and the output port E21. The resistor section R22 is provided between the ground port G2 and the output port E21. The resistor section R23 is provided between the ground port G2 and the output port E22. The resistor section R24 is provided between the power supply port V2 and the output port E22.

A voltage or current of a specific magnitude is applied to the power supply port V2. The ground port G2 is connected to the ground.

The magnetic sensor 40 further includes two differential amplifiers (difference detectors) 413 and 414. Two input ports of the differential amplifier 413 are connected to the two output ports E11 and E12. Two input ports of the differential amplifier 414 are connected to the two output ports E21 and E22. The differential amplifier 413 is configured to output a signal corresponding to a potential difference of the two output ports E11 and E12. The differential amplifier 414 is configured to output a signal corresponding to a potential difference of the two output ports E21 and E22.

The first detection signal S1 which is the cosine signal may be a signal itself corresponding to the potential difference of the two output ports E11 and E12, or may be a signal obtained by applying specific corrections, such as gain adjustment and offset adjustment, to this signal. The second detection signal S2 which is the sine signal may be a signal itself corresponding to the potential difference of the two output ports E21 and E22, or may be a signal obtained by applying specific corrections, such as gain adjustment and offset adjustment, to this signal. In the following description, unless otherwise specified, the first detection signal S1 is assumed to be the signal itself corresponding to the potential difference of the two output ports E11 and E12, and the second detection signal S2 is assumed to be the signal itself corresponding to the potential difference of the two output ports E21 and E22.

The magnetic sensor 40 further includes a sensor chip 400 on which the first and second bridge circuits 411 and 412 are formed, and a sensor package (not shown) covering the sensor chip 400. The sensor chip 400 includes a plurality of sensor arrays and a plurality of bonding pads 401. The plurality of sensor arrays include four sensor arrays A11, A12, A13, and A14 corresponding to the four resistor sections R11, R12, R13, R14, respectively, and four sensor arrays A21, A22, A23, and A24 corresponding to the four resistor sections R21, R22, R23, and R24, respectively. The plurality of bonding pads 401 include one bonding pad connected to the power supply port V1 and the power supply port V2, one bonding pad connected to the ground port G1 and the ground port G2, and four bonding pads corresponding to the four output ports E11, E12, E21, and E22. Note that the plurality of bonding pads 401 may include two bonding pads corresponding to the power supply ports V1 and V2, instead of the one bonding pad connected to the power supply port V1 and the power supply port V2. Furthermore, the plurality of bonding pads 401 may include two bonding pads corresponding to the ground ports G1 and G2, instead of the one bonding pad connected to the ground port G1 and the ground port G2.

FIG. 5 shows a first example of an arrangement of the plurality of resistor sections of the first bridge circuit 411 and the second bridge circuit 412. In the first example, the two sensor arrays A11 and A12 corresponding to the two resistor sections R11 and R12 are arranged in this order in the −Y direction. The sensor array A13 corresponding to the resistor section R13 is arranged on the side of the X direction with respect to the sensor array A12 corresponding to the resistor section R12. The sensor array A14 corresponding to the resistor section R14 is arranged on the side of the X direction with respect to the sensor array A11 corresponding to the resistor section R11.

The two sensor arrays A21 and A22 corresponding to the two resistor sections R21 and R22 are arranged in this order in the −Y direction. The sensor array A23 corresponding to the resistor section R23 is arranged on the side of the X direction with respect to the sensor array A22 corresponding to the resistor section R22. The sensor array A24 corresponding to the resistor section R24 is arranged on the side of the X direction with respect to the sensor array A21 corresponding to the resistor section R21.

The sensor array A21 corresponding to the resistor section R21 is arranged on the −Y direction with respect to the sensor array A12 corresponding to the resistor section R12. The sensor array A24 corresponding to the resistor section R24 is arranged on the side of the −Y direction with respect to the sensor array A13 corresponding to the resistor section R13.

FIG. 6 shows a second example of an arrangement of the plurality of resistor sections of the first bridge circuit 411 and the second bridge circuit 412. In the second example, the four sensor arrays A11, A12, A13, and A14 corresponding to the four resistor sections R11, R12, R13, and R14 are arranged to align in this order along the −Y direction. The four sensor arrays A21, A22, A23, and A24 corresponding to the four resistor sections R21, R22, R23, and R24 are arranged to align in this order along the −Y direction. The sensor array A21 corresponding to the resistor section R21 is arranged on the side of the −Y direction with respect to the sensor array A14 corresponding to the resistor section R14.

Next, an angle output value generated by a system including the magnetic sensor system 120 will be described. The system generates an angle output value θ_{A} using the first detection signal S1 which is the cosine signal and the second detection signal S2 which is the sine signal, for example. The angle output value θ_{A} can be generated, for example, by the following Equation (1). Note that S1 represents the magnitude of the first detection signal S1, and S2 represents the magnitude of the second detection signal S2.

θ_{A}=arctan(S2/S1) (1)

Equation (1) represents the fact that an arctangent operation is performed using the first and second detection signals S1 and S2. The angle output value θ_{A} varies at a frequency twice a frequency of a magnetization angle described later.

Next, a configuration of the plurality of resistor sections of the first bridge circuit 411 and the second bridge circuit 412 will be described. In the example embodiment, the magnetic detection element is an AMR element 450. The AMR element 450 contains a ferromagnetic metal material such as Ni and Fe, and has a shape long in one direction, for example. The AMR element 450 is formed from NiFe, CoFe, or the like, for example. In the AMR element 450, the magnetoresistive effect occurs when the magnetization direction of the AMR element 450 forms a specific relative angle with respect to a direction of current flowing through the AMR element 450.

Here, the XZ plane including the detection position is referred to as a first plane, and a plane inclined with respect to both the first plane and the XY plane is referred to as a second plane. The first plane and the second plane intersect at a dihedral angle other than 90°. The magnetic sensor 40 includes a slope structure 420 having a slope to detect at least one of the direction or the strength of the target magnetic field in the second plane by the AMR element 450. The slope is perpendicular to the YZ plane and inclined with respect to both the XY plane and the XZ plane. The AMR element 450 is disposed on the slope. The slope may have a plane, may have a curved surface, or may have a plane and a curved surface. For convenience, in the following description and the drawings, the slope is assumed to be a plane.

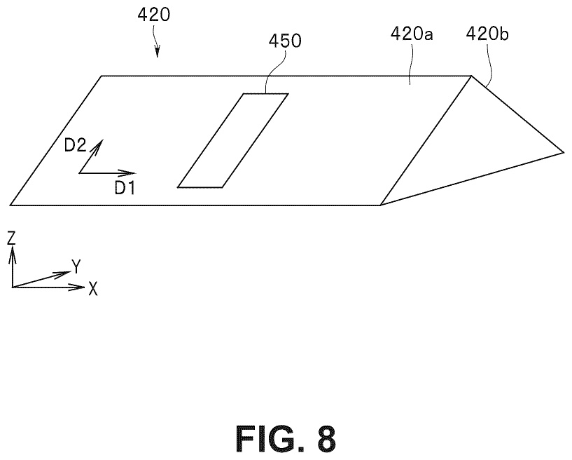

FIG. 8 is a perspective view showing the AMR element 450 and the slope structure 420. The slope structure 420 may be, for example, formed by an insulating layer formed on a sensor substrate and composed of an insulating material. In addition, the slope structure 420 also has a first slope 420a and a second slope 420b inclined with respect to the Z-axis direction and a surface of the sensor substrate, as slopes. The first slope 420a and the second slope 420b are directed to different directions from each other. A normal direction of the first slope 420a and a normal direction of the second slope 420b may be symmetric about the XZ plane. The first slope 420a and the second slope 420b may be directly connected or connected via another surface, such as a flat surface.

The slope structure 420 has a shape long in the X-axis direction. Each of the first and second slopes 420a and 420b is a surface parallel to a surface formed by inclining the XZ plane about an axis parallel to the X direction. The first slope 420a is a surface parallel to a surface formed by inclining the XZ plane toward the Y direction. The second slope 420b is a surface parallel to a surface formed by inclining the XZ plane toward the −Y direction. FIG. 8 shows the slope structure 420 seen from the side of the first slope 420a.

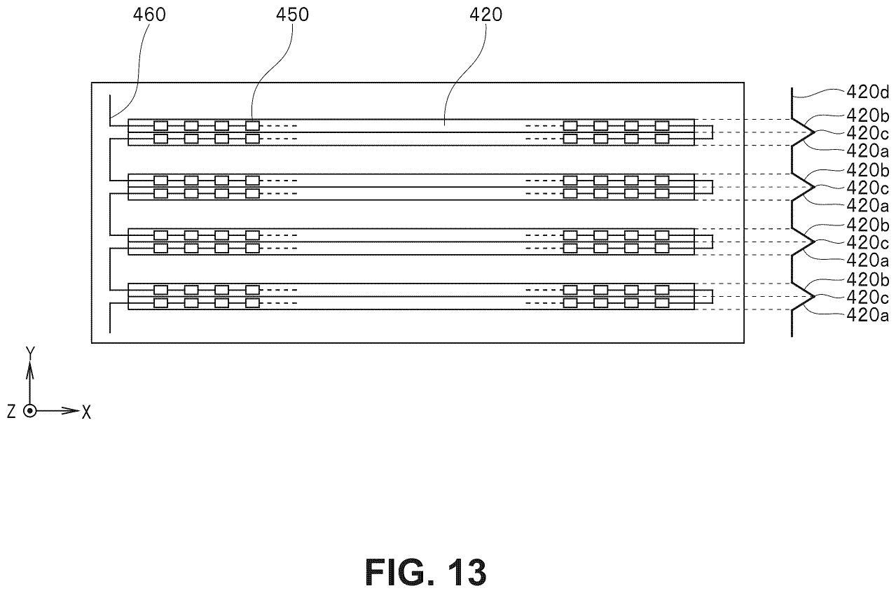

The magnetic sensor 40 includes the plurality of AMR elements 450 disposed on the first and second slopes 420a and 420b, and wirings 460 connecting the plurality of AMR elements 450. Note that the wirings 460 are shown in FIG. 13 described later. The wirings 460 include two wiring materials (two electrodes) connected to both ends of the AMR element 450 in a longitudinal direction. The wiring material is formed of, for example, a material with high electrical conductivity, such as Cu and Au. Current flows through the AMR element in the longitudinal direction of the AMR element via the two wiring materials (two electrodes).

The magnetic sensor 40 detects the target magnetic field in which at least one of the direction or the strength thereof changes in the first plane (XZ plane) by utilizing the anisotropic magnetoresistive effect of the AMR elements 450 arranged on the slope structure 420. The target magnetic field includes the magnetic field component Bx and the magnetic field component Bz. The magnetization of the AMR element 450 rotates in the second plane due to the target magnetic field. The second plane corresponding to the AMR element has a correspondence with the first slope 420a or the second slope 420b, and is inclined with respect to both the first plane and the XY plane. When the first slope 420a is a plane, the second plane corresponding to the AMR element 450 may be parallel to the first slope 420a. When the first slope 420a is a curved surface, the second plane corresponding to the AMR element 450 may be parallel to the tangent line at a part of the first slope 420a where the AMR element 450 is in contact.

When the second slope 420b is a plane, the second plane corresponding to the AMR element 450 may be parallel to the second slope 420b. When the second slope 420b is a curved surface, the second plane corresponding to the AMR element 450 may be parallel to the tangent line at a part of the second slope 420b where the AMR element 450 is in contact.

In the AMR element 450, a change in resistance due to the anisotropic magnetoresistive effect occurs depending on an angle formed by the direction of the current flowing through the AMR element 450 with the magnetization direction of the AMR element 450. This enables the magnetic sensor 40 to acquire a detection signal as angle information of the target magnetic field.

Here, in FIG. 8, a slope coordinate system defined by a first arrow labeled the symbol D1 and a second arrow labeled the symbol D2 will be described. The slope coordinate system is defined for both the first slope 420a and the second slope 420b. The arrow labeled the symbol D1 represents a first direction D1 in the slope coordinate system and coincides with the X direction of the reference coordinate system. The arrow labeled the symbol D2 represents a second direction D2 in the slope coordinate system. In the slope coordinate system corresponding to the first slope 420a, the second direction D2 is a direction obtained by projecting the Z direction of the reference coordinate system onto the first slope 420a and coincides with a direction rotated by a from the Y direction toward the Z direction. In the slope coordinate system corresponding to the second slope 420b, the second direction D2 is a direction obtained by projecting the Z direction of the reference coordinate system onto the second slope 420b and coincides with a direction rotated by B from the −Y direction toward the Z direction. Note that a and B are angles greater than 0° and less than 90°. In addition, a and B may be equal to each other or different from each other. Furthermore, a and B may be constant regardless of the position in the Z direction and the position in the Y direction, or may vary depending on the position in the Z direction and the position in the Y direction.

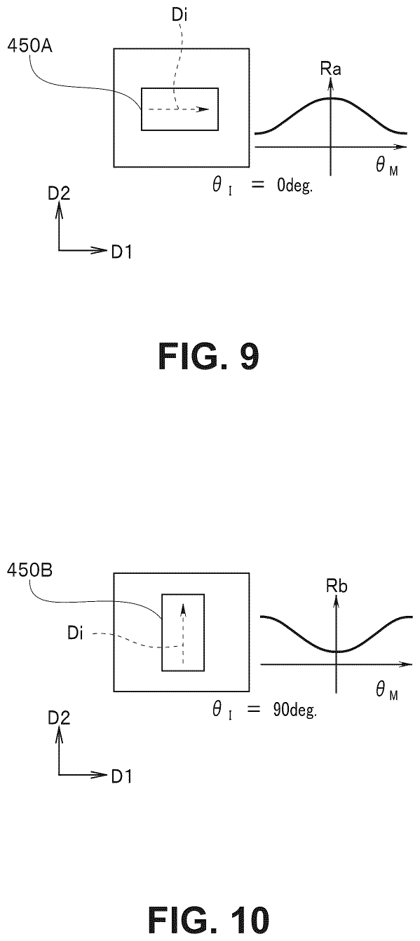

Next, with reference to FIG. 9 to FIG. 12, four types of AMR elements that can be used in the first bridge circuit 411 and the second bridge circuit 412 will be described.

Here, definitions of a current angle and the magnetization angle will be described. A current angle θ_{I} and a magnetization angle θ_{M} are defined in the slope coordinate system corresponding to the AMR element. In the example embodiment, an angle formed by a direction of current I flowing through the AMR element with the reference direction is referred to as the current angle θ_{I}. In addition, an angle formed by a direction of magnetization M of the AMR element with the reference direction is referred to as the magnetization angle θ_{M}. In the examples shown in FIG. 9 to FIG. 12, the reference direction is the first direction D1 of the slope coordinate system. The current angle θ_{I} and the magnetization angle θ_{M} may be represented by a value of 0° or more and less than 360°.

The resistance of the AMR elements is expressed using the current angle θr and the magnetization angle θ_{M} by the following Equation (2). Note that R₀ represents a resistance of the AMR element when the direction of the current I and the direction of the magnetization M of the AMR element are orthogonal to each other, and MR represents an MR ratio of the AMR element.

R=R₀(1+MR cos²(θ_{M}−θ_{I})) (2)

FIG. 9 is an explanatory diagram for describing a first AMR element 450A which is a first magnetoresistive element. The arrow labeled Di in FIG. 9 represents a current direction. The first AMR element 450A is configured such that the current angle θ_{I} is 0°. A resistance Ra of the first AMR element 450A changes periodically in response to changes in the magnetization angle θ_{M}. The first AMR element 450A may be used as an AMR element 450 for constituting the resistor sections R12 and R14 of the first bridge circuit 411.

FIG. 10 is an explanatory diagram for describing a second AMR element 450B which is a second magnetoresistive element. The second AMR element 450B is configured such that the current angle θ_{I} is 90°. A resistance Rb of the second AMR element 450B changes periodically in response to changes in the magnetization angle θ_{M}. The second AMR element 450B may be used as an AMR element 450 for constituting the resistor sections R11 and R13 of the first bridge circuit 411.

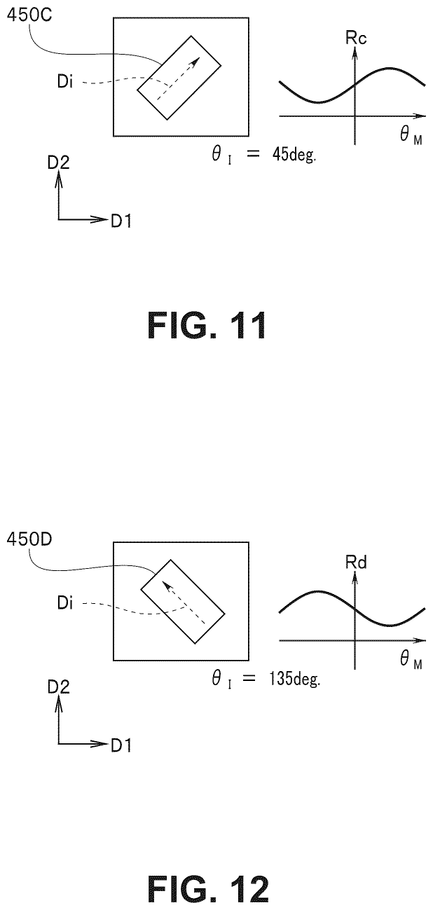

FIG. 11 is an explanatory diagram for describing a third AMR element 450C which is a third magnetoresistive element. The third AMR element 450C is configured such that the current angle θ_{I} is 45°. A resistance Rc of the third AMR element 450C changes periodically in response to changes in the magnetization angle θ_{M}. The third AMR element 450C may be used as an AMR element 450 for constituting the resistor sections R22 and R24 of the second bridge circuit 412.

FIG. 12 is an explanatory diagram for describing a fourth AMR element 450D which is a fourth magnetoresistive element. The fourth AMR element 450D is configured such that the current angle θ_{I} is 135°. A resistance Rd of the fourth AMR element 450D changes periodically in response to changes in the magnetization angle θ_{M}. The fourth AMR element 450D may be used as an AMR element 450 for constituting the resistor sections R21 and R23 of the second bridge circuit 412.

As described above, the resistance R of the AMR element 450 has a correspondence with the magnetization angle θ_{M}. In the first to fourth AMR elements 450A, 450B, 450C, and 450D shown in FIG. 9 to FIG. 12, the magnetization angle θ_{M} has a correspondence with the target magnetic field in which at least one of the direction or the strength thereof changes in the first plane (XZ plane). Therefore, when the first and second bridge circuits 411 and 412 are configured using the first to fourth AMR elements 450A, 450B, 450C, and 450D, the resistances of the resistor sections R11 to R14 and R21 to R24 each vary in response to the target magnetic field, and the magnitudes of the first and second detection signals S1 and S2 each vary in response to the target magnetic field. In addition, since the target magnetic field includes the magnetic field component Bx and the magnetic field component Bz, the resistances of the resistor sections R11 to R14 and R21 to R24 and the magnitudes of the first and second detection signals S1 and S2 each vary in response to the magnetic field component Bx and the magnetic field component Bz.

Note that the configurations of the first to fourth AMR elements 450A, 450B, 450C, and 450D are not limited to the examples shown in FIG. 9 to FIG. 12. For example, the first to fourth AMR elements 450A, 450B, 450C, and 450D may be configured such that the reference direction of the current angle θ_{I} is a direction other than the first direction D1 of the slope coordinate system. In this case, the difference between the current angle θ_{I} of the first AMR element 450A and the current angle θ_{I} of the second AMR element 450B may be 90° or may be an angle other than 90°. Similarly, the difference between the current angle θ_{I} of the third AMR element 450C and the current angle θ_{I} of the fourth AMR element 450D may be 90° or may be an angle other than 90°. In addition, the difference between the current angle θ_{I} of the first AMR element 450A and the current angle θ_{I} of the third AMR element 450C may be 45° or may be an angle other than 45°.

Next, a configuration of the plurality of resistor sections of the first bridge circuit 411 and the second bridge circuit 412 will be described. FIG. 13 is a plan view showing the plurality of AMR elements 450, which are the plurality of magnetoresistive elements, and the plurality of slope structures 420 in any one resistor section. Each of the plurality of resistor sections includes the plurality of AMR elements 450 as the plurality of magnetoresistive elements, the plurality of slope structures 420, and wirings 460 connecting the plurality of AMR elements 450. In each of the plurality of sensor arrays, the plurality of slope structures 420 are aligned along the Y direction. Each of the plurality of slope structures 420 has a ridge 420c, which is a boundary where the first slope 420a and the second slope 420b intersect, and which is long in one direction. The ridge 420c extends along the X direction.

In each of the first slope 420a and the second slope 420b, the plurality of AMR elements 450 are arranged along the X direction. The wirings 460 connect the plurality of AMR elements 450.

A flat surface 420d exists around the plurality of slope structures 420. Each of the plurality of slope structures 420 may have a protrusion portion protruding from the flat surface 420d in the Z direction. Alternatively, each of the plurality of slope structures 420 may be formed in a groove portion recessed from the flat surface 420d in the −Z direction.

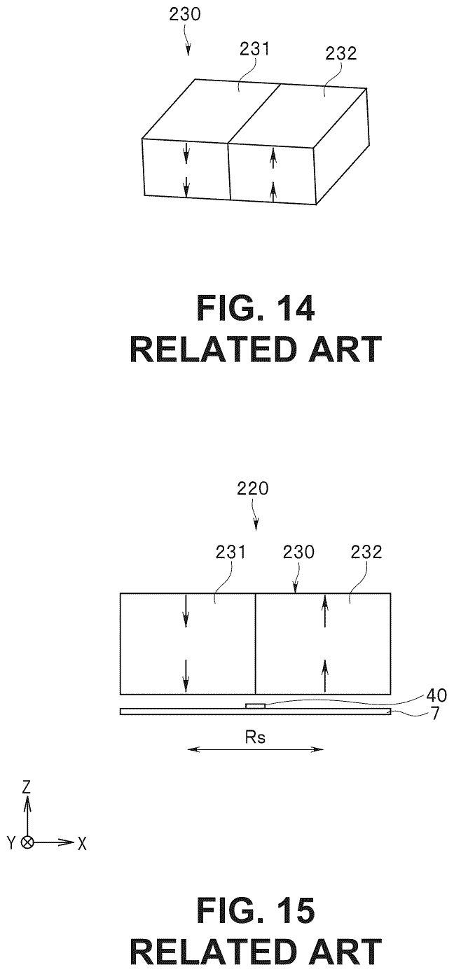

Next, working and effects of the magnetic sensor system 120 according to the example embodiment will be described in comparison with a magnetic sensor system 220 of a comparative example including a magnetic field generator 230 of the comparative example. First, with reference to FIG. 14 and FIG. 15, a configuration of the magnetic sensor system 220 of the comparative example will be described. FIG. 14 is a perspective view showing the magnetic field generator 230 of the comparative example. FIG. 15 is a side view showing the magnetic sensor system 220 of the comparative example.

The magnetic field generator 230 of the comparative example has a rectangular parallelepiped shape. In addition, the magnetic field generator 230 includes two parts 231 and 232. The part 231 is magnetized to include a magnetization component in the −Z direction. The part 232 is magnetized to include a magnetization component in the Z direction. In FIG. 14 and FIG. 15, the arrows drawn to overlap the part 231 represent the magnetization direction of the part 231, and the arrows drawn to overlap the part 232 represent the magnetization direction of the part 232.

The magnetic field generator 230 has a top surface located at an end in the Z direction, a bottom surface located at an end in the −Z direction, a first side surface located at an end in the −X direction, and a second side surface located at an end in the X direction. Each of the top surface and the bottom surface is a surface parallel to the XY plane. Each of the first side surface and the second side surface is a surface parallel to the YZ plane. The dimension of the magnetic field generator 230 in the Z-axis direction is the same as the maximum dimension of the magnetic field generator 30 in the Z-axis direction. The dimension of the part 231 in the X-axis direction is the same as the dimension of the part 31 in the X-axis direction. The dimension of the part 232 in the X-axis direction is the same as the dimension of the part 32 in the X-axis direction. The distance between the center of the part 231 in the X-axis direction and the center of the part 232 in the X-axis direction is the same as the distance between the center of the part 31 in the X-axis direction and the center of the part 32 in the X-axis direction.

The configuration of the magnetic sensor system 220 of the comparative example is the same as the configuration of the magnetic sensor system 120 according to the example embodiment, except that the magnetic field generator 230 is provided instead of the magnetic field generator 30 in the example embodiment.

Next, the magnetic field generated by the magnetic field generator 30 in the example embodiment and the magnetic field generated by the magnetic field generator 230 of the comparative example will be described. In the following description, among the magnetic field generated by the magnetic field generator 30 in the example embodiment and the magnetic field generated by the magnetic field generator 230 of the comparative example, a magnetic field component in the X-axis direction is referred to as a first magnetic field, a magnetic field component in the Y-axis direction is referred to as a second magnetic field, and a magnetic field component in the Z-axis direction is referred to as a third magnetic field. In addition, the first to third magnetic fields of the magnetic field generated by the magnetic field generator 30 in the example embodiment are referred to as the first to third magnetic fields in the example embodiment. Furthermore, the first to third magnetic fields of the magnetic field generated by the magnetic field generator 230 of the comparative example are referred to as the first to third magnetic fields of the comparative example.

As described above, the target magnetic field at the detection position includes the magnetic field component Bx which is the component in the X-axis direction, the magnetic field component By which is the component in the Y-axis direction, and the magnetic field component Bz which is the component in the Z-axis direction. The magnetic field component Bx corresponds to the first magnetic field at the detection position. The magnetic field component By corresponds to the second magnetic field at the detection position. The magnetic field component Bz corresponds to the third magnetic field at the detection position.

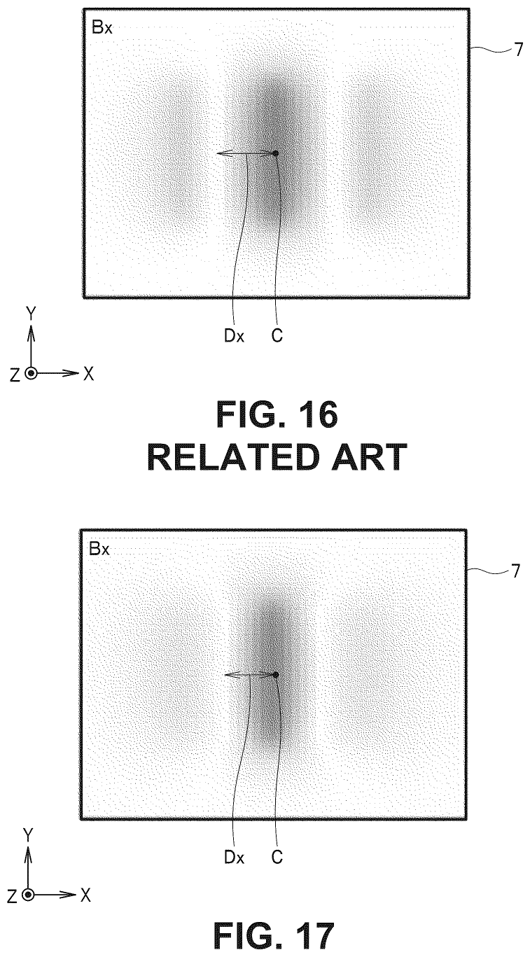

FIG. 16 is an image showing a distribution of strengths of the first magnetic field of the comparative example in the XY plane (the top surface 7a of the substrate 7, for example). FIG. 17 is an image showing a distribution of strengths of the first magnetic field in the example embodiment in the XY plane (the top surface 7a of the substrate 7, for example). In FIG. 16 and FIG. 17, for convenience, the symbol Bx is used to represent the first magnetic field. In addition, in FIG. 16 and FIG. 17, the direction and the strength of the first magnetic field are shown by grayscale in the image. As the strength of the first magnetic field approaches zero, the image becomes brighter. Note that in figures similar to FIG. 16 and FIG. 17 used for descriptions below, the direction and the strength of the magnetic field are represented using the same manner as in FIG. 16 and FIG. 17.

The center of the rectangle labeled the reference sign 7 in FIG. 16 and FIG. 17 may coincide with the center of the movable range of the magnetic sensor 40 when seen from the magnetic field generator 30. The magnetic sensor 40 when seen from the magnetic field generator 30 can move in both the X direction and the −X direction from the center C of the rectangle labeled the reference sign 7. As understood from FIG. 16 and FIG. 17, the strength of the first magnetic field is greatest at the center C. In addition, in FIG. 16 and FIG. 17, the arrow labeled the symbol Dx indicates the distance from the center C to a position where the strength of the first magnetic field becomes zero. As understood from FIG. 16 and FIG. 17, in the magnetic field generator 30 in the example embodiment, the distance Dx is smaller compared to the distance Dx for the magnetic field generator 230 of the comparative example.

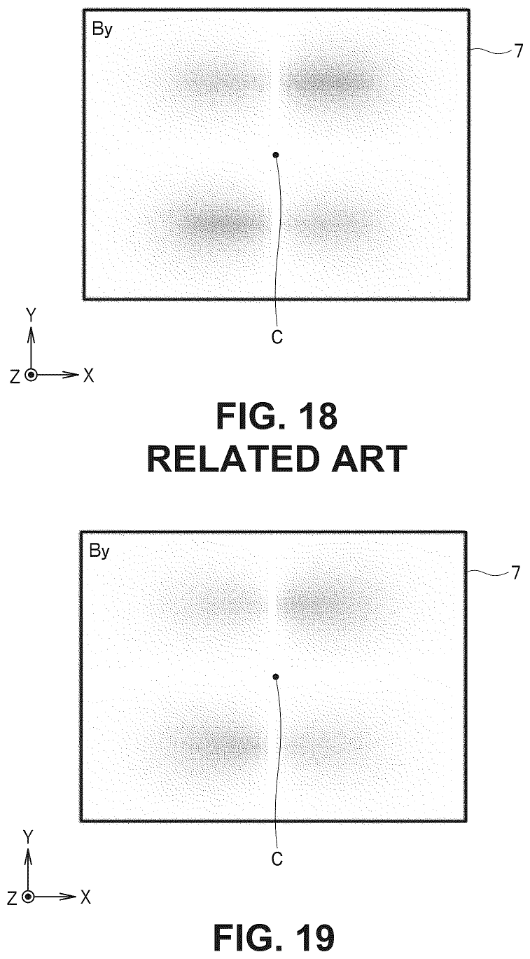

FIG. 18 is an image showing a distribution of strengths of the second magnetic field of the comparative example in the XY plane (the top surface 7a of the substrate 7, for example). FIG. 19 is an image showing a distribution of strengths of the second magnetic field in the example embodiment in the XY plane (the top surface 7a of the substrate 7, for example). In FIG. 18 and FIG. 19, for convenience, the symbol By is used to represent the second magnetic field. As understood from FIG. 18 and FIG. 19, at the center of the rectangle labeled the reference sign 7 in FIG. 18 and FIG. 19, the strength of the second magnetic field becomes zero or nearly zero. In addition, in the movable range of the magnetic sensor 40 when seen from the magnetic field generator 30, the strength of the second magnetic field becomes zero or nearly zero.

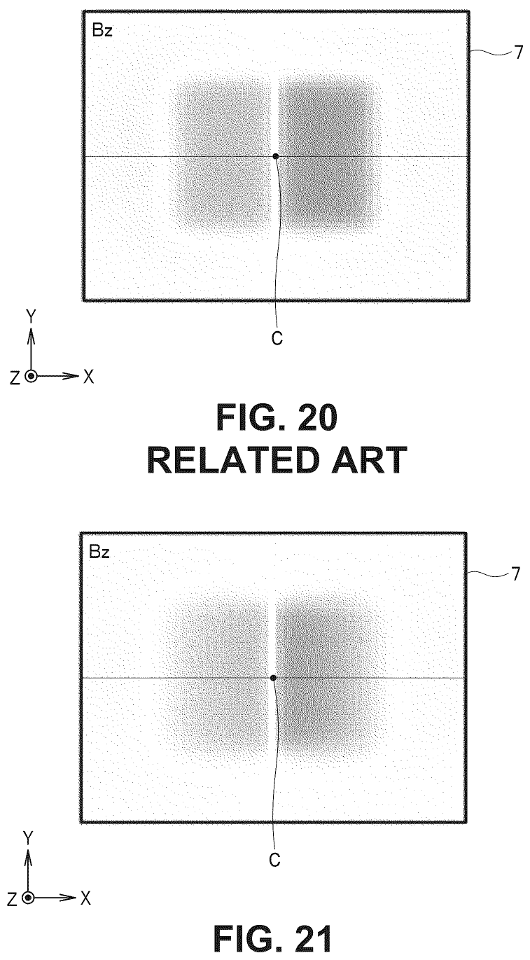

FIG. 20 is an image showing a distribution of strengths of the third magnetic field of the comparative example in the XY plane (the top surface 7a of the substrate 7, for example). FIG. 21 is an image showing a distribution of strengths of the third magnetic field in the example embodiment in the XY plane (the top surface 7a of the substrate 7, for example). In FIG. 20 and FIG. 21, for convenience, the symbol Bz is used to represent the third magnetic field. In addition, as understood from FIG. 20 and FIG. 21, at the center of the rectangle labeled the reference sign 7 in FIG. 20 and FIG. 21, the strength of the third magnetic field becomes zero or nearly zero. In addition, the strength of the third magnetic field increases as moving from the center C in the X direction and the −X direction, respectively.

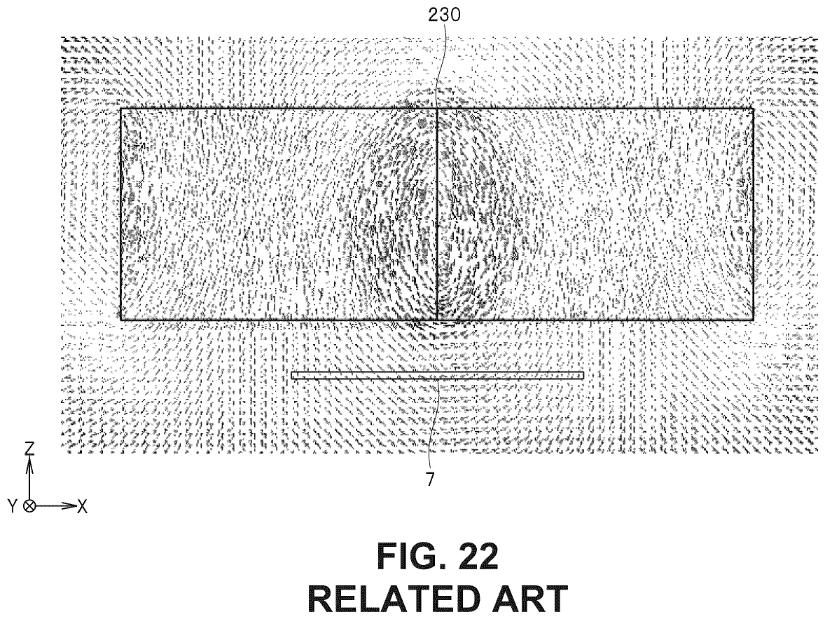

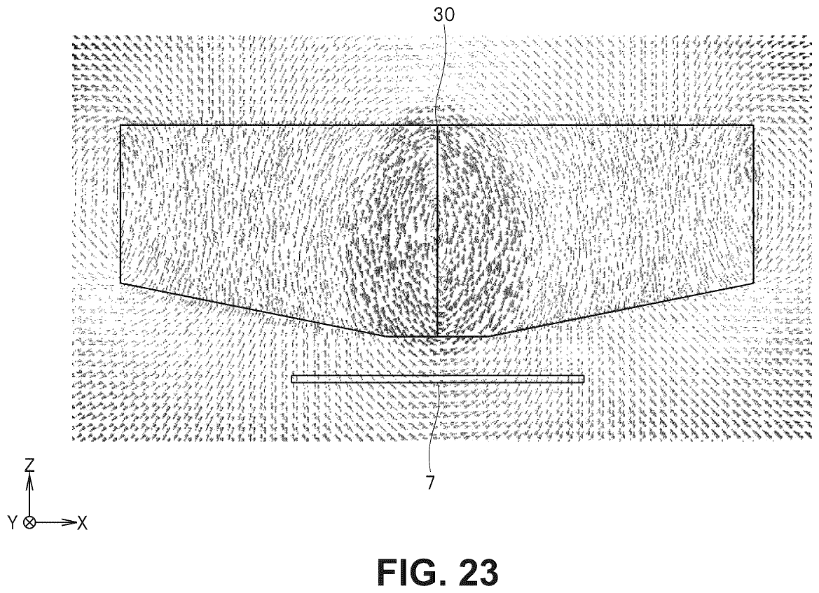

FIG. 22 is an image showing a distribution of the directions of the magnetic field generated by the magnetic field generator 230 of the comparative example. FIG. 23 is an image showing a distribution of the directions of the magnetic field generated by the magnetic field generator 30 in the example embodiment. The direction of the magnetic field that is generated by the magnetic field generator 30, at the position intersecting the substrate 7, changes at smaller intervals compared to the direction of the magnetic field generated by the magnetic field generator 230 of the comparative example. As understood from FIG. 22 and FIG. 23, in the example embodiment, a spatial periodicity of the magnetic field becomes smaller compared to the comparative example.

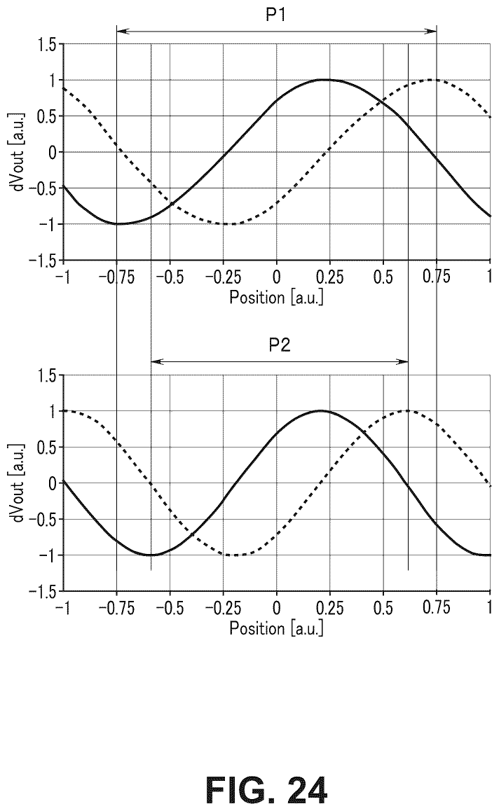

Next, with reference to FIG. 24, the first and second detection signals S1 and S2 of the magnetic sensor 40 in the example embodiment (hereinafter, referred to as the first and second detection signals in the example embodiment) and the first and second detection signals of the magnetic sensor of the magnetic sensor system 220 of the comparative example (hereinafter, referred to as the first and second detection signals of the comparative example) corresponding to the first and second detection signals S1 and S2 of the magnetic sensor 40 in the example embodiment will be described. An upper waveform chart in FIG. 24 is a waveform chart showing the detection signal of the comparative example. A lower waveform chart in FIG. 24 is a waveform chart showing the first and second detection signals in the example embodiment. In FIG. 24, the solid curves represent one of the first detection signal and the second detection signal, and the dashed curves represent the other of the first detection signal and the second detection signal. Furthermore, in FIG. 24, the label “Position” of the horizontal axis indicates the relative position of the magnetic sensor 40 when seen from the magnetic field generator 30. The label “dVout” of the vertical axis indicates the magnitude of each of the first and second detection signals.

As understood from FIG. 24, in the example embodiment, the magnitude of the relative position from the maximum value to the minimum value in each of the first detection signal and the second detection signal is smaller compared to the comparative example. Furthermore, a relative position where the first detection signal is the maximum value is referred to as a first position, and a relative position where the second detection signal is the maximum value is referred to as a second position. In FIG. 24, the distance between the first position and the second position in the comparative example is represented by the arrow labeled the reference sign P1. The distance P1 includes the minimum value of one of the first detection signal and the second detection signal of the comparative example and the maximum value of the other of the first detection signal and the second detection signal of the comparative example. Furthermore, in FIG. 24, the distance between the first position and the second position in the example embodiment is represented by the arrow labeled the reference sign P2. The distance P2 includes the minimum value of one of the first detection signal and the second detection signal in the example embodiment and the maximum value of the other of the first detection signal and the second detection signal in the example embodiment. As shown in FIG. 24, the distance P2 is smaller than the distance P1.

In the comparative example, the distance P1 is the same or substantially the same as a distance between the center of the first part 231 of the magnetic field generator 230 in the X-axis direction and the center of the second part 232 of the magnetic field generator 230 in the X-axis direction. In contrast, in the example embodiment, the magnetic field generator 30 is configured such that the distance P2 is smaller than a distance between the center of the part 31 of the magnetic field generator 30 in the X-axis direction and the center of the part 32 of the magnetic field generator 30 in the X-axis direction. Specifically, the magnetic field generator 30 is configured to have the shape described with reference to FIG. 3 and FIG. 4. Therefore, the distance P2 is smaller than the distance P1. In addition, the distance P1 substantially represents the distance between the center of the part 31 in the X-axis direction and the center of the part 32 in the X-axis direction. FIG. 24 shows that the distance P2 is smaller than the distance between the center of the part 31 in the X-axis direction and the center of the part 32 in the X-axis direction.

In the comparative example, when the movable range of the magnetic sensor 40 when seen from the magnetic field generator 230 is narrower than the distance P1, it may not be possible to detect the maximum and minimum values of both the first detection signal and the second detection signal. In this case, it may not be possible to perform offset correction and amplitude correction for each of the first detection signal and the second detection signal. In contrast, according to the example embodiment, even when the movable range is narrower than the distance P1, the maximum and minimum values of both the first detection signal and the second detection signal can be detected. The movable range may be smaller than the distance P1 and larger than the distance P2. According to the example embodiment, it is possible to perform offset correction and amplitude correction for both the first detection signal and the second detection signal, thereby reducing errors in the angle output value θ_{A}.

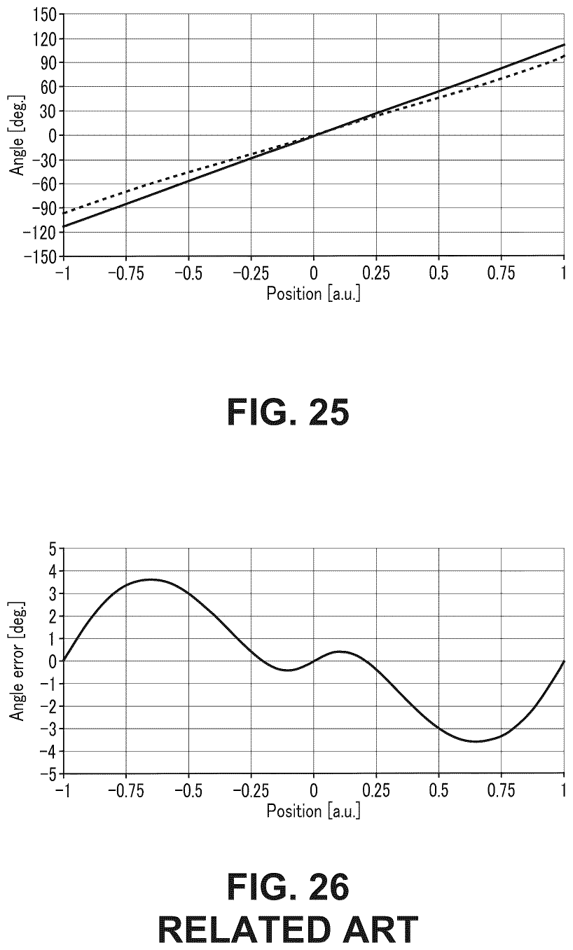

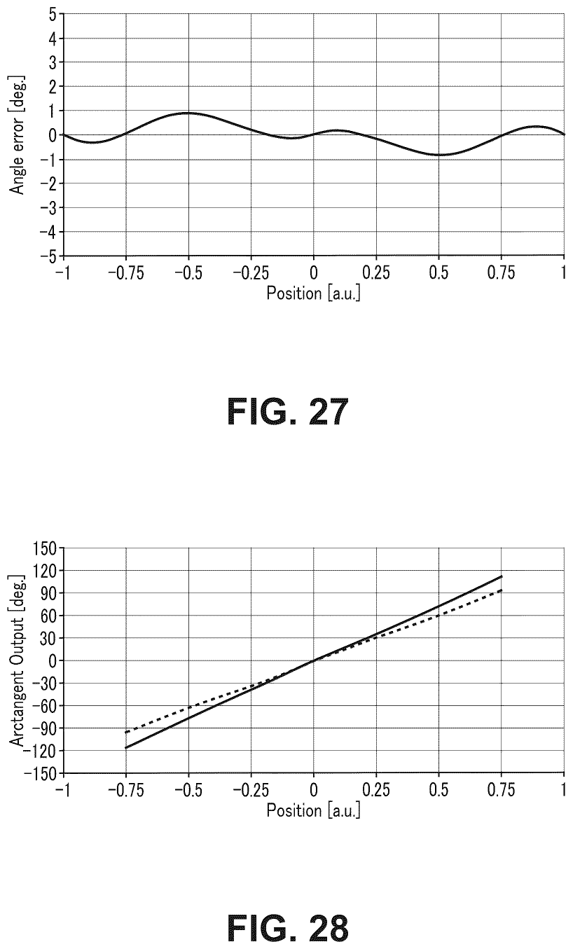

Next, the direction of the target magnetic field at each detection position of the magnetic sensor system 220 of the comparative example and the magnetic sensor system 120 according to the example embodiment will be described. Hereinafter, the direction of the target magnetic field will be described using the magnetic field angle, which is an angle formed by the direction of the target magnetic field with the X direction. Here, the magnetic field angle in the magnetic sensor system 220 of the comparative example is referred to as a magnetic field angle of the comparative example, and the magnetic field angle in the magnetic sensor system 120 according to the example embodiment is referred to as a magnetic field angle in the example embodiment. FIG. 25 is a characteristic diagram showing the magnetic field angle of the comparative example and the magnetic field angle in the example embodiment. In FIG. 25, the label “Position” of the horizontal axis indicates the relative position and the label “Angle” indicates the magnetic field angle. In addition, in FIG. 25, the solid line indicates the magnetic field angle in the example embodiment, and the dashed line indicates the magnetic field angle of the comparative example. Furthermore, FIG. 26 is a characteristic diagram showing errors in the magnetic field angle of the comparative example. FIG. 27 is a characteristic diagram showing errors in the magnetic field angle in the example embodiment. In FIG. 26 and FIG. 27, the label “Position” of the horizontal axis indicates the relative position and the label “Angle error” indicates the errors in the magnetic field angle. Note that in FIG. 26 and FIG. 27, a difference between the magnetic field angle assumed when the direction of the target magnetic field changes ideally and the actual magnetic field angle is defined as an error in the magnetic field angle.

As shown in FIG. 25, an inclination of the magnetic field angle (the rate of the change in the magnetic field angle with respect to the change in the relative position) in the example embodiment indicated by the solid line is larger than an inclination of the magnetic field angle of the comparative example indicated by the dashed line. Furthermore, as shown in FIG. 26 and FIG. 27, the errors in the magnetic field angle in the example embodiment are smaller compared to the errors in the magnetic field angle of the comparative example. Consequently, according to the example embodiment, the detection accuracy can be improved.

FIG. 28 is a characteristic diagram showing the angle output value θ_{A} of the comparative example and the angle output value θ_{A} in the example embodiment. The angle output value θ_{A} of the comparative example is the angle output value θ_{A} in the magnetic sensor system 220 of the comparative example. The angle output value θ_{A} in the example embodiment is the angle output value θ_{A} in the magnetic sensor system 120 according to the example embodiment. In FIG. 28, the label “Position” of the horizontal axis indicates the relative position and the label “Arctangent Output” indicates the angle output value θ_{A}.

Here, the definition of linearity of the angle output value θ_{A} will be described. The linearity is defined using a characteristic curve (see FIG. 28) representing a correspondence between the relative position and the angle output value θ_{A} and an approximation line for this characteristic curve. At each of the plurality of relative positions, the linearity is a value obtained by dividing the maximum residual between a value on the approximation line and a value on the characteristic curve by the magnitude of the variable range of the angle output value θ_{A}. A smaller the value of the linearity indicates better linearity. Furthermore, the linearity has a correspondence with the errors in the angle output value θ_{A}. The smaller the linearity value, the smaller the errors in the angle output value θ_{A}. In the example shown in FIG. 28, the linearity of the angle output value θ_{A} of the comparative example is 0.8%, and the linearity of the angle output value θ_{A} in the example embodiment is 0.4%. Therefore, according to the example embodiment, the linearity can be improved and the errors in the angle output value θ_{A} can be reduced.

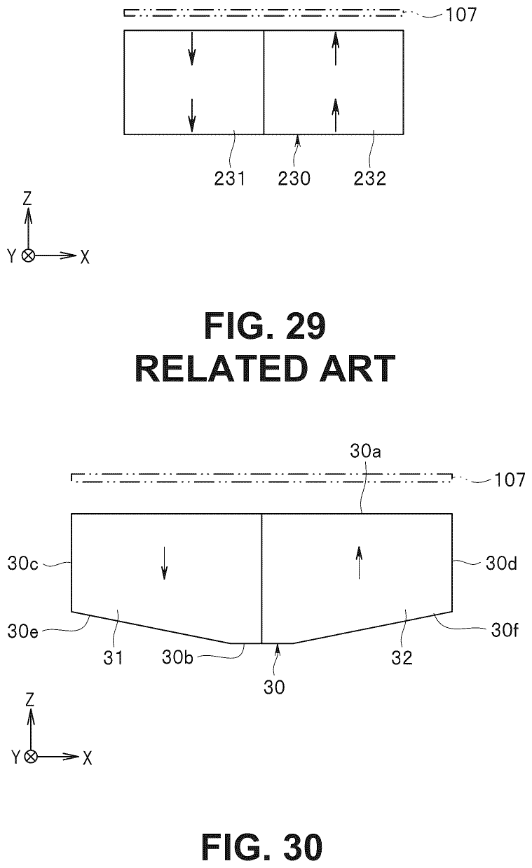

Next, a magnetic field in a region near the magnetic field generator 30 where no magnetic sensor 40 is provided will be described, in comparison to the magnetic field generator 230 of the comparative example. First, with reference to FIG. 29 and FIG. 30, an imaginary substrate 107 will be described. FIG. 29 is a side view showing the magnetic field generator 230 and the imaginary substrate 107 of the comparative example. FIG. 30 is a side view showing the magnetic field generator 30 and the imaginary substrate 107 in the example embodiment.

The imaginary substrate 107 is assumed to have a top surface and a bottom surface, each parallel to the XY plane. In the comparative example, the imaginary substrate 107 is assumed to be disposed on the side of the Z direction with respect to the magnetic field generator 230 in the Z direction, and to be disposed such that the bottom surface of the imaginary substrate 107 faces the top surface of the magnetic field generator 230 at a distance. The distance between the magnetic field generator 230 and the imaginary substrate 107 may be the same as a distance between the magnetic field generator 230 and the substrate 7. Similarly, in the example embodiment, the imaginary substrate 107 is assumed to be disposed on the side of the Z direction with respect to the magnetic field generator 30 in the Z direction, and to be disposed such that the bottom surface of the imaginary substrate 107 faces the top surface 30a of the magnetic field generator 30 at a distance. The distance between the magnetic field generator 30 and the imaginary substrate 107 may be the same as a distance between the magnetic field generator 30 and the substrate 7.

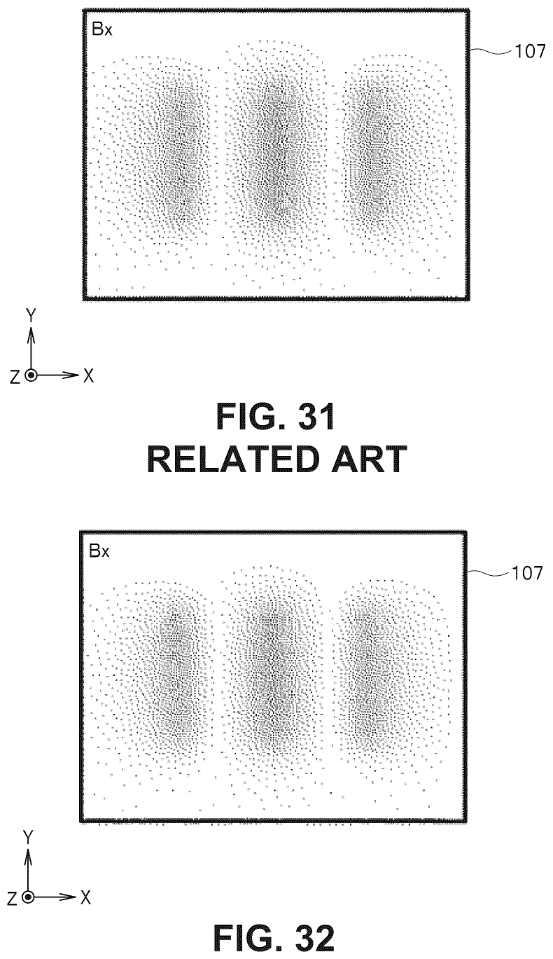

FIG. 31 is an image showing a distribution of the strengths of the first magnetic field in the top surface or the bottom surface (XY plane) of the imaginary substrate 107 of the comparative example. FIG. 32 is an image showing a distribution of the strengths of the first magnetic field in the top surface or the bottom surface (XY plane) of the imaginary substrate 107 in the example embodiment. In FIG. 31 and FIG. 32, for convenience, the symbol Bx is used to represent the first magnetic field.

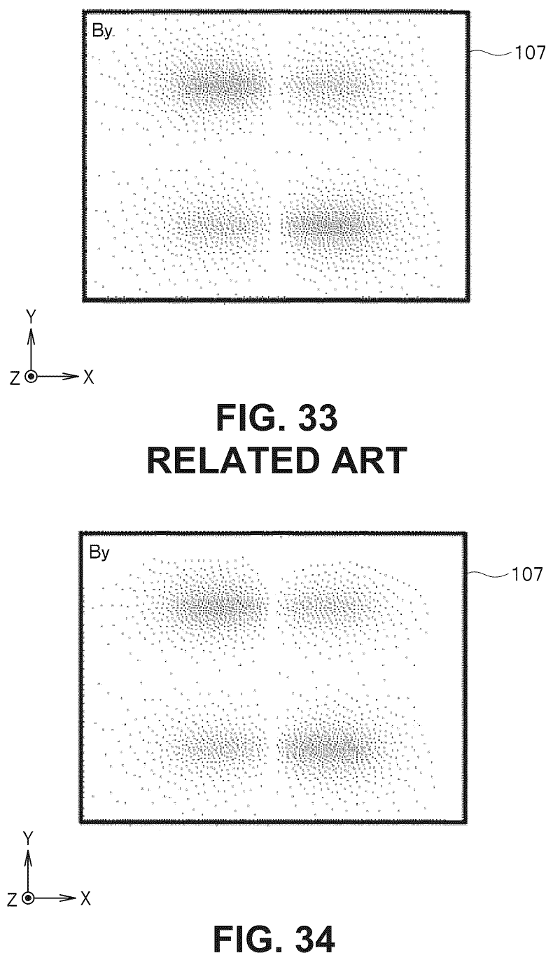

FIG. 33 is an image showing a distribution of the strengths of the second magnetic field in the top surface or the bottom surface (XY plane) of the imaginary substrate 107 of the comparative example. FIG. 34 is an image showing a distribution of the strengths of the second magnetic field in the top surface or the bottom surface (XY plane) of the imaginary substrate 107 in the example embodiment. In FIG. 33 and FIG. 34, for convenience, the symbol By is used to represent the second magnetic field.

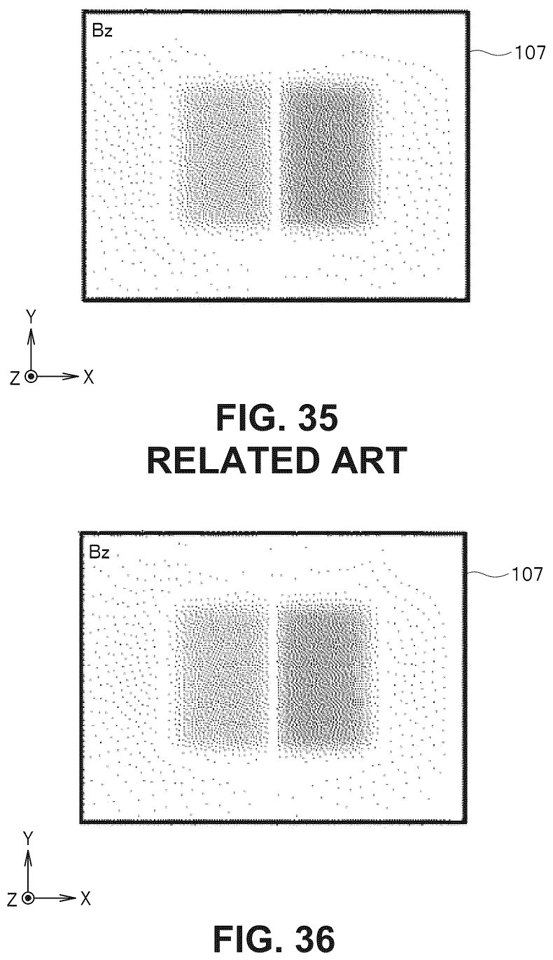

FIG. 35 is an image showing a distribution of the strengths of the third magnetic field in the top surface or the bottom surface (XY plane) of the imaginary substrate 107 of the comparative example. FIG. 36 is an image showing a distribution of the strengths of the third magnetic field in the top surface or the bottom surface (XY plane) of the imaginary substrate 107 in the example embodiment. In FIG. 35 and FIG. 36, for convenience, the symbol Bz is used to represent the third magnetic field.

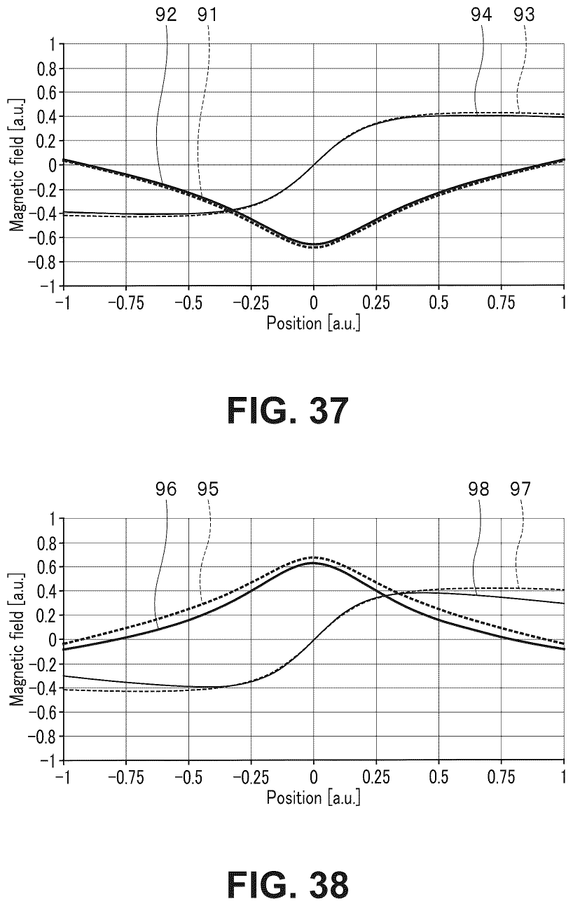

FIG. 37 is a characteristic diagram showing the magnitude of the first magnetic field of the comparative example shown in FIG. 31, the magnitude of the first magnetic field in the example embodiment shown in FIG. 32, the magnitude of the third magnetic field of the comparative example shown in FIG. 35, and the magnitude of the third magnetic field in the example embodiment shown in FIG. 36. In FIG. 37, the label “Position” of the horizontal axis indicates the position on a first imaginary straight line intersecting the center of the rectangle labeled the reference sign 107 (the center of the planar shape of the imaginary substrate 107) in FIG. 31, FIG. 32, FIG. 35, and FIG. 36, and parallel to the X direction. The label “Magnetic Field” of the vertical axis indicates the magnitude of each of the first and third magnetic fields. Furthermore, in FIG. 37, the curve labeled the reference sign 91 indicates the magnitude of the first magnetic field of the comparative example shown in FIG. 31. The curve labeled the reference sign 92 indicates the magnitude of the first magnetic field in the example embodiment shown in FIG. 32. The curve labeled the reference sign 93 indicates the magnitude of the third magnetic field of the comparative example shown in FIG. 35. The curve labeled the reference sign 94 indicates the magnitude of the third magnetic field in the example embodiment shown in FIG. 36. FIG. 37 shows the magnitude of the first magnetic field and the magnitude of the third magnetic field on the above first imaginary straight line.

FIG. 38 is a characteristic diagram showing the magnitude of the first magnetic field of the comparative example shown in FIG. 16, the magnitude of the first magnetic field in the example embodiment shown in FIG. 17, the magnitude of the third magnetic field of the comparative example shown in FIG. 20, and the magnitude of the third magnetic field in the example embodiment shown in FIG. 21. In FIG. 38, the horizontal axis indicates the position on a second imaginary straight line intersecting the center of the rectangle labeled the reference sign 7 (the center of the planar shape of the substrate 7) in FIG. 16, FIG. 17, FIG. 20, and FIG. 21, and parallel to the X direction. The label “Magnetic Field” of the vertical axis indicates the magnitude of each of the first and third magnetic fields. Furthermore, in FIG. 38, the curve labeled the reference sign 95 indicates the magnitude of the first magnetic field of the comparative example shown in FIG. 16. The curve labeled the reference sign 96 indicates the magnitude of the first magnetic field in the example embodiment shown in FIG. 17. The curve labeled the reference sign 97 indicates the magnitude of the third magnetic field of the comparative example shown in FIG. 20. The curve labeled the reference sign 98 indicates the magnitude of the third magnetic field in the example embodiment shown in FIG. 21. FIG. 38 shows the magnitude of the first magnetic field and the magnitude of the third magnetic field on the above second imaginary straight line.

From FIG. 16 to FIG. 21 and FIG. 38, it can be seen that in the region where the substrate 7 is disposed and where the magnetic sensor 40 is provided near the magnetic field generator 30, the magnetic field generated by the magnetic field generator 30 in the example embodiment is different from the magnetic field generated by the magnetic field generator 230 of the comparative example. On the other hand, from FIG. 31 to FIG. 37, it can be seen that in the region where the imaginary substrate 107 is disposed and where the magnetic sensor 40 is not provided near the magnetic field generator 30, there is almost no difference between the magnetic field generated by the magnetic field generator 30 in the example embodiment and the magnetic field generated by the magnetic field generator 230 of the comparative example. In addition to the magnetic sensor 40, other components such as coils or holding members other than the magnetic sensor system 120 can be arranged around the magnetic field generator 30. According to the example embodiment, the magnetic field generator 30 can be used instead of the magnetic field generator 230, while suppressing the effect on other components. In particular, on the side of the top surface 30a of the magnetic field generator 30, other components can be arranged under the same conditions as the magnetic field generator 230.

### Modification Example

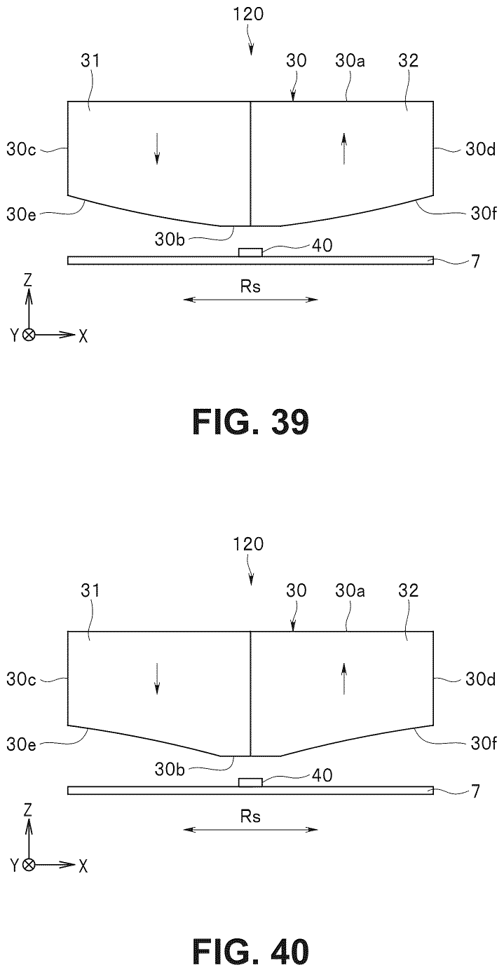

Next, modification examples of the magnetic field generator 30 according to the example embodiment will be described. First, with reference to FIG. 39, a first modification example of the magnetic field generator 30 will be described. In the first modification example, each of a first connection surface 30e and a second connection surface 30f of the magnetic field generator 30 is a protruding surface protruding outward from the magnetic field generator 30. When the first modification example of the magnetic field generator 30 is applied to the magnetic sensor system 120 according to the example embodiment, the linearity of the angle output value θ_{A} is 0.7%, for example.

Next, with reference to FIG. 40, a second modification example of the magnetic field generator 30 will be described. In the second modification example, each of a first connection surface 30e and a second connection surface 30f of the magnetic field generator 30 is a recessed surface recessed toward the inside of the magnetic field generator 30. When the second modification example of the magnetic field generator 30 is applied to the magnetic sensor system 120 according to the example embodiment, the linearity of the angle output value θ_{A} is 0.2%, for example.

### Second Example Embodiment

Next, a second example embodiment of the disclosure will be described. In the example embodiment, a first bridge circuit 411 of a magnetic sensor 40 (see FIG. 7) is configured to detect the magnetic field component Bx of the target magnetic field. A second bridge circuit 412 of the magnetic sensor 40 (see FIG. 7) is configured to detect the magnetic field component Bz of the target magnetic field.

In addition, in the example embodiment, the magnetic sensor 40 includes a plurality of spin-valve magnetoresistive elements 50 instead of the plurality of AMR elements. Hereinafter, the spin-valve magnetoresistive element 50 is referred to as an MR element 50.

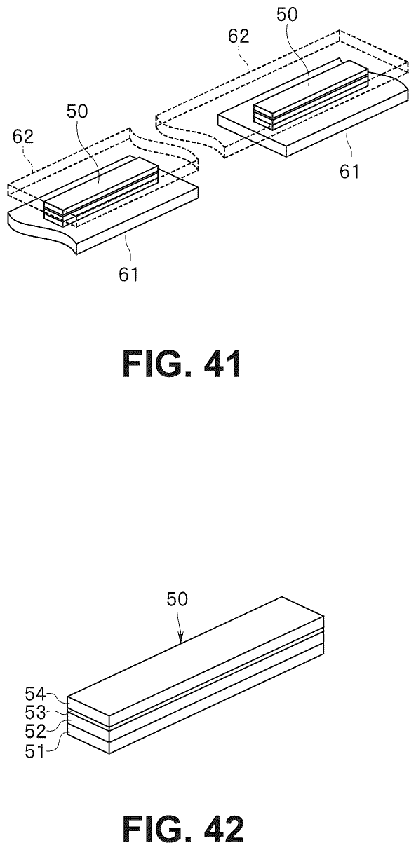

Each of the plurality of resistor sections of the first and second bridge circuits 411 and 412 of the magnetic sensor 40 shown in FIG. 7 in the first example embodiment includes at least one MR element 50. Each of the plurality of resistor sections may include a plurality of MR elements 50 connected in series. Here, with reference to FIG. 41, an example of a configuration of the plurality of resistor sections will be described. FIG. 41 is a perspective view showing a part of one resistor section of the plurality of resistor sections. In this example, the one resistor section includes a plurality of lower electrodes 61, the plurality of MR elements 50, and a plurality of upper electrodes 62. The plurality of lower electrodes 61 are disposed on a substrate (not shown). Each of the lower electrodes 61 has a long slender shape. A gap is formed between two lower electrodes 61 adjacent in the longitudinal direction of the lower electrodes 61. On the top surface of each of the lower electrodes 61, the MR elements 50 are disposed near both ends in the longitudinal direction, respectively. Each of the upper electrodes 62 is disposed on the two lower electrodes 61 adjacent in the longitudinal direction of the lower electrodes 61 to electrically connect two adjacent MR elements 50. This configuration connects the plurality of MR elements 50 in series via the plurality of lower electrodes 61 and the plurality of upper electrodes 62.

FIG. 42 is a perspective view showing the MR element 50. The MR element 50 includes a magnetization pinned layer 52 whose magnetization direction is fixed, a free layer 54 whose magnetization direction is variable in response to the target magnetic field, and an intermediate layer 53 disposed between the magnetization pinned layer 52 and the free layer 54. The MR element 50 may be a tunnel magnetoresistive (TMR) element, or a giant magnetoresistive (GMR) element. In the TMR element, the intermediate layer is a tunnel barrier layer. In the GMR element, the intermediate layer is a nonmagnetic conductive layer. In the MR element 50, the resistance changes depending on the angle formed by the magnetization direction of the free layer 54 with the magnetization direction of the magnetization pinned layer 52. The resistance is a minimum value when this angle is 0°, and is a maximum value when this angle is 180°. The MR element 50 further includes an antiferromagnetic layer 51. The antiferromagnetic layer 51, the magnetization pinned layer 52, the intermediate layer 53, and the free layer 54 are stacked in this order. The antiferromagnetic layer 51 is formed of an antiferromagnetic material and is in exchange coupling with the magnetization pinned layer 52, thereby fixing the magnetization direction of the magnetization pinned layer 52. Note that the magnetization pinned layer 52 may be a so-called self-pinned layer (Synthetic Ferri Pinned layer, SPF layer). The self-pinned layer has a stacked ferri structure in which a ferromagnetic layer, a nonmagnetic intermediate layer, and a ferromagnetic layer are stacked, and the two ferromagnetic layers are coupled antiferromagnetically. When the magnetization pinned layer 52 is the self-pinned layer, the antiferromagnetic layer 51 may be omitted.

Note that the arrangement of the layers 51 to 54 in each MR element 50 may be inverted vertically relative to the arrangement shown in FIG. 42.

Next, the first and second bridge circuits 411 and 412 (see FIG. 7) in the example embodiment composed of the plurality of MR elements 50 will be described.

The magnetization of the magnetization pinned layer 52 of the MR element 50 in the resistor sections R11 and R13 of the first bridge circuit 411 and the resistor sections R21 and R23 of the second bridge circuit 412 may include the component in the −X direction. The magnetization of the magnetization pinned layer 52 of the MR element 50 in the resistor sections R12 and R14 of the first bridge circuit 411 and the resistor sections R22 and R24 of the second bridge circuit 412 may include the component in the X direction. In addition, the MR element 50 may have a shape long in the Y-axis direction. Consequently, the free layer 54 of the MR element 50 may have shape anisotropy such that a direction of the magnetization easy axis is the Y-axis direction.

Note that when the magnetization of the magnetization pinned layer 52 includes a component in a specific direction, the component in the specific direction may be a main component of the magnetization of the magnetization pinned layer 52. In the example embodiment, when the magnetization of the magnetization pinned layer 52 includes the component in the specific direction, the magnetization direction of the magnetization pinned layer 52 is the specific direction or substantially the specific direction.

In the first bridge circuit 411, the resistance of each of the resistor sections R11 to R14 and the magnitude of the first detection signal S1 vary in response to the magnetic field component Bx of the target magnetic field.

The second bridge circuit 412 further includes at least one yoke formed of a soft magnetic body. The at least one yoke has a shape long in the Y-axis direction in planar view from the Z direction, that is, when seen from the above, for example. In addition, the at least one yoke is configured to receive an input magnetic field including the magnetic field component Bz which is an input magnetic field component in the Z-axis direction, to generate an output magnetic field. The output magnetic field includes an output magnetic field component which is in the X-axis direction and varies in response to the input magnetic field component. The at least one yoke corresponds to a magnetic field converter that receives the magnetic field component Bz to generate a detection component in the Z-axis direction.

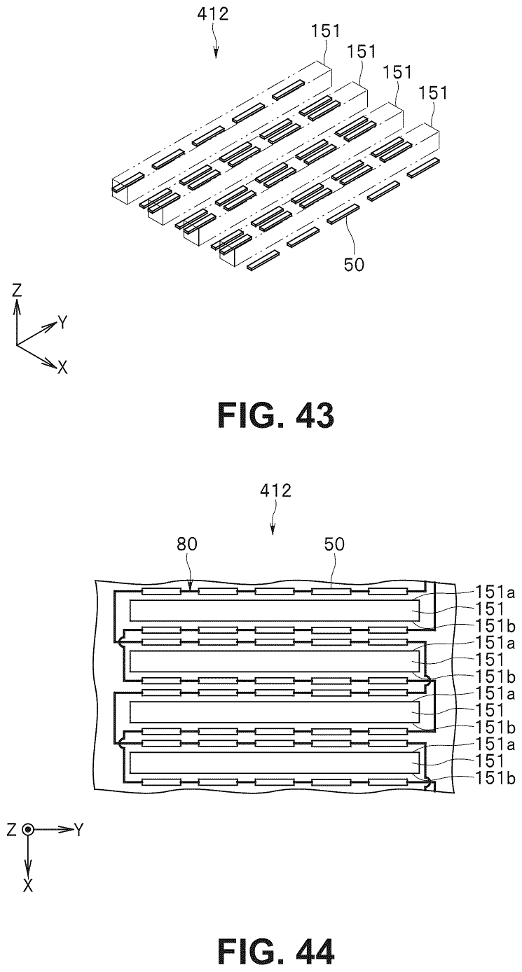

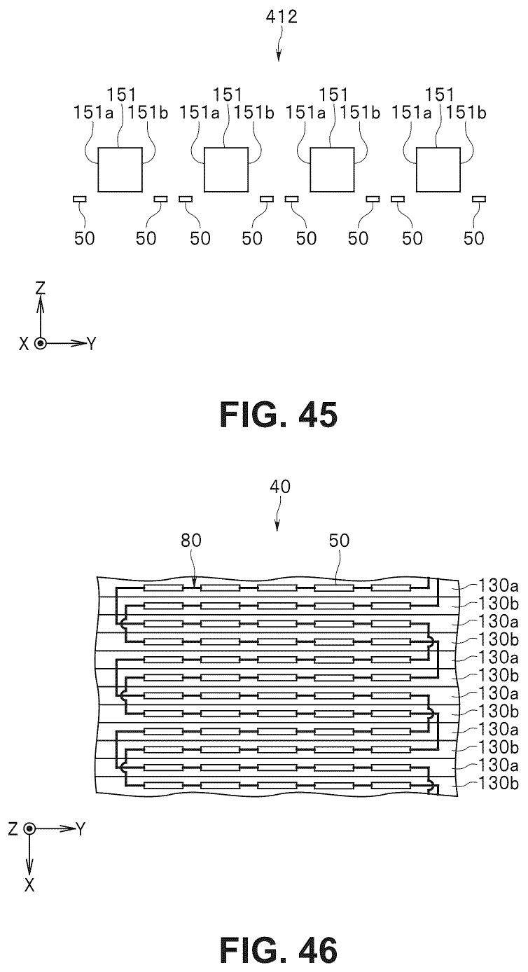

Hereinafter, with reference to FIG. 43, FIG. 44, and FIG. 45, a configuration of the second bridge circuit 412 will be described in detail. FIG. 43 is a perspective view showing a part of the second bridge circuit 412. FIG. 44 is a plan view showing a part of the second bridge circuit 412. FIG. 45 is a perspective view showing a part of the second bridge circuit 412. As shown in FIG. 43 to FIG. 45, in particular in the example embodiment, the magnetic sensor 40 includes a plurality of yokes 151 arranged to align in the X-axis direction, as at least one yoke. Each of the plurality of yokes 151 has a rectangular parallelepiped shape long in the Y-axis direction, for example. The shapes of the plurality of yokes 151 are the same. Each of the plurality of yokes 151 has a first end surface 151a and a second end surface 151b located at both ends thereof in the X-axis direction. In each of the plurality of yokes 151, the first end surface 151a is located at an end in the −X direction, and the second end surface 151b is located at an end in the X direction.

The magnetic sensor 40 further includes a wiring 80 connecting the plurality of MR elements 50 in series. The wiring 80 includes the plurality of lower electrodes 61 and the plurality of upper electrodes 62.

Here, focusing on one yoke 151, the positional relationship between the plurality of MR elements 50 and the yoke 151 will be described. Some of the plurality of MR elements 50 (hereinafter, referred to as a plurality of first MR elements 50) are arranged near the first end surface 151a of the yoke 151 to align along the yoke 151 in the Y-axis direction. Other ones of the plurality of MR elements 50 (hereinafter, referred to as a plurality of second MR elements 50) are arranged near the second end surface 151b of the yoke 151 to align along the yoke 151 in the Y-axis direction.

The wiring 80 connects, among the plurality of yokes 151, the plurality of first MR elements 50 arranged near the first end surface 151a of one of two adjacent yokes 151 at a distance and the plurality of first MR elements 50 arranged near the first end surface 151a of the other of the two adjacent yokes 151. The wiring 80 connects, among the plurality of yokes 151, the plurality of second MR elements 50 arranged near the second end surface 151b of one of the two adjacent yokes 151 at a distance and the plurality of second MR elements 50 arranged near the second end surface 151b of the other of the two adjacent yokes 151.

In the second bridge circuit 412, the resistance of each of the resistor sections R21 to R24 and the magnitude of the second detection signal S2 vary in response to the output magnetic field component generated by the yokes 151. The output magnetic field component varies in response to the magnetic field component Bz of the target magnetic field. Therefore, the resistance of each of the resistor sections R21 to R24 and the magnitude of the second detection signal S2 vary in response to the magnetic field component Bz of the target magnetic field.

Other configurations, working, and effects in the example embodiment are similar to those in the first example embodiment.

### Third Example Embodiment

Next, a third example embodiment of the disclosure will be described. In the example embodiment, the first and second bridge circuits 411 and 412 of the magnetic sensor 40 (see FIG. 7) detect the target magnetic field in which at least one of the direction or the strength of the target magnetic field varies in the first plane (XY plane). The target magnetic field includes the magnetic field component Bx and the magnetic field component Bz.

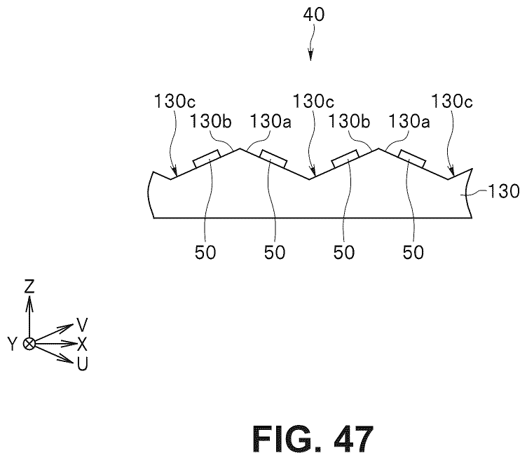

Hereinafter, with reference to FIG. 46 and FIG. 47, a configuration of the magnetic sensor 40 according to the example embodiment will be described with respect to the points differing from the second example embodiment. FIG. 46 is a plan view showing a part of the magnetic sensor 40. FIG. 47 is a cross-sectional view showing a part of the magnetic sensor 40. In the example embodiment, the plurality of yokes 151 in the second example embodiment are not provided. In addition, the magnetic sensor 40 includes a support member 130 that supports the plurality of MR elements 50. The support member 130 includes a sensor substrate and an insulating portion formed of an insulating material. The sensor substrate has a top surface parallel to the XY plane.

The support member 130 has a plurality of protruding surfaces 130c. Each of the plurality of protruding surfaces 130c extends in the Y-axis direction. Each of the plurality of protruding surfaces 130c may be a part of a protrusion portion protruding from a flat portion of the support member, or may be a part of a groove portion recessed from the flat portion of the support member.

Each of the plurality of protruding surfaces 130c has a slope 130a and a slope 130b inclined with respect to the top surface of the sensor substrate (XY plane). The slopes 130a and 130b may have a plane, may have a curved surface, or may have a plane and a curved surface. The plurality of first MR elements 50, which are some of the plurality of MR elements 50, are arranged to align in the Y-axis direction on the respective slopes 130a of the plurality of protruding surfaces 130c. The plurality of second MR elements 50, which are some other of the plurality of MR elements 50, are arranged to align in the Y-axis direction on the respective slopes 130b of the plurality of protruding surfaces 130c.

The wiring 80 connects, among the plurality of protruding surfaces 130c, the plurality of first MR elements 50 arranged on the slope 130a of one of two adjacent protruding surfaces 130c at a distance and the plurality of first MR elements 50 arranged on the slope 130a of the other of the two adjacent protruding surfaces 130c. In addition, the wiring 80 connects, among the plurality of protruding surfaces 130c, the plurality of second MR elements 50 arranged on the slope 130b of one of two adjacent protruding surfaces 130c at a distance and the plurality of second MR elements 50 arranged on the slope 130b of the other of the two adjacent protruding surfaces 130c.

Here, as shown in FIG. 47, a U direction and a V direction are defined as follows. The U direction is a direction rotated from the X direction toward the −Z direction. The V direction is a direction rotated from the X direction toward the Z direction. In particular in the example embodiment, the U direction is a direction rotated by a from the X direction toward the −Z direction, and the V direction is a direction rotated by a from the X direction toward the Z direction. Note that a is an angle greater than 0° and less than 90°. In addition, a direction opposite the U direction is defined as a −U direction, and a direction opposite the V direction is defined as a −V direction.

The slope 130a may have a plane parallel to a YU plane, and may have a curved surface contacting the YU plane. The plurality of first MR elements 50 may be arranged on the plane parallel to the YU plane, and may be arranged on the curved surface contacting the YU plane. In addition, the slope 130b may have a plane parallel to a YV plane, or may have a curved surface contacting the YV plane. The plurality of second MR elements 50 may be arranged on the plane parallel to a YV plane, or may be arranged on the curved surface contacting the YV plane.

Next, the first and second bridge circuits 411 and 412 (see FIG. 7) in the example embodiment composed of the plurality of MR elements 50 will be described. In particular in the example embodiment, the first bridge circuit 411 is composed of the plurality of first MR elements 50, and the second bridge circuit 412 is composed of the plurality of second MR elements 50.

The magnetization of the magnetization pinned layer 52 of the first MR elements 50 in the resistor sections R11 and R13 of the first bridge circuit 411 may include a component in the −U direction. The magnetization of the magnetization pinned layer 52 of the first MR elements 50 in the resistor sections R12 and R14 of the first bridge circuit 411 may include a component in the U direction. In addition, the first MR element 50 may have a shape long in the Y-axis direction. Consequently, the free layer 54 of the first MR element 50 may have shape anisotropy such that the direction of the magnetization easy axis is the Y-axis direction.

The magnetization of the magnetization pinned layer 52 of the second MR elements 50 in the resistor sections R21 and R23 of the second bridge circuit 412 may include a component in the −V direction. The magnetization of the magnetization pinned layer 52 of the second MR elements 50 in the resistor sections R22 and R24 of the second bridge circuit 412 may include a component in the V direction. In addition, the second MR element 50 may have a shape long in the Y-axis direction. Consequently, the free layer 54 of the second MR element 50 may have shape anisotropy such that the direction of the magnetization easy axis is the Y-axis direction.

The target magnetic field detected by the magnetic sensor 40 can be divided into a first component in a direction parallel to the U direction, and a second component in a direction parallel to a direction orthogonal to the U direction. The first bridge circuit 411 is configured to detect the first component of the target magnetic field. When the strength of the first component of the target magnetic field changes, the resistance of each of the resistor sections R11 to R14 and the magnitude of the first detection signal S1 change.

In addition, the target magnetic field detected by the magnetic sensor 40 can be divided into a third component in a direction parallel to the V direction, and a fourth component in a direction parallel to a direction orthogonal to the V direction. The second bridge circuit 412 is configured to detect the third component of the target magnetic field. When the strength of the third component of the target magnetic field changes, the resistance of each of the resistor sections R21 to R24 and the magnitude of the second detection signal S2 change.

Furthermore, the target magnetic field includes the magnetic field component Bx and the magnetic field component Bz. The magnetic sensor system 120 or a system including the magnetic sensor system 120 includes a processor (not shown). The processor (not shown) generates a detection value Sx corresponding to the magnetic field component Bx and a detection value Sz corresponding to the magnetic field component Bz based on the first and second detection signals S1 and S2.

The processor (not shown) calculates values Sxp and Szp using the following Equations (3) and (4), for example. Note that S1 represents the magnitude of the first detection signal S1, and S2 represents the magnitude of the second detection signal S2.

$$Sxp = ( S 2 + S 1 ) / ( 2 cos α ) \qquad ( 3 )$$

$$Szp = ( S 2 - S 1 ) / ( 2 sin α ) \qquad ( 4 )$$

The detection value Sx may be the value Sxp itself, or may be the value Sxp with specific corrections applied, such as gain adjustment and offset adjustment. Similarly, the detection value Sz may be the value Szp itself, or may be the value Szp with specific corrections applied, such as gain adjustment and offset adjustment.

Furthermore, the processor (not shown) may generate the angle output value θ_{A} using the detection values Sx and Sz. The angle output value θ_{A} can be generated, for example, using the following Equation (5). Note that Sx represents the magnitude of the detection value Sx, and Sz represents the magnitude of the detection value Sz.

$${θ}_{A} = arctan ( Sz / Sx ) \qquad ( 5 )$$

Other configurations, working, and effects in the example embodiment are similar to those in the second example embodiment.

Note that the disclosure is not limited to the above example embodiments, and various modifications are possible. For example, the magnetic sensor system according to the disclosure can be applied to a switch mechanism as follows. The switch mechanism is, for example, a mechanism including a movable portion that can be displaced by a user operation on a key switch, a trigger switch, a button switch, or the like. The movable portion may be, for example, a key top, a trigger, or a button. In the switch mechanism, it is necessary to detect the position or a displacement amount of the movable portion accompanying the operation. The magnetic sensor system according to the disclosure can be used to detect the position of the movable portion. In this case, the magnetic sensor system may be configured such that the magnetic field generator moves in conjunction with the movement of the movable portion. This enables analog output and on/off determination corresponding to an amount of switch depression or stroke.

Note that the above-described embodiments can be appropriately combined within the scope where no technical contradictions arise between them. Furthermore, the embodiments should not be interpreted as being mutually exclusive or limited. It is possible to extract part of specific configurations or operations described in one embodiment and apply them to other embodiments, or substitute them for configurations in other embodiments. Thus, configurations obtained by combining the embodiments with each other, or by combining or modifying parts included in the embodiments, also fall within the scope of the technical idea of the disclosure.

As described above, the magnetic sensor system according to one embodiment of the disclosure includes the magnetic field generator including the first part and the second part aligned in the first direction, the first part being magnetized to include the magnetization component in the second direction orthogonal to the first direction, the second part being magnetized to include the magnetization component in the third direction opposite to the second direction, and the magnetic sensor configured to detect the magnetic field generated by the magnetic field generator at the detection position. The magnetic field generator and the magnetic sensor are configured such that the relative position, which is a relative position of the magnetic field generator with respect to the magnetic sensor, changes in a direction parallel to the first direction. The magnetic sensor is configured to generate the first detection signal and the second detection signal, which change in response to the relative position and have the phases different from each other, based on the magnetic field. The first detection signal is the maximum value when the relative position is the first position. The second detection signal is the maximum value when the relative position is the second position. The magnetic field generator is configured such that the distance between the first position and the second position is smaller than the distance between the center of the first part in the first direction and the center of the second part in the first direction.

In the magnetic sensor system according to one embodiment of the disclosure, a phase difference between the first detection signal and the second detection signal with respect to the change in the relative position may be 90° electrical angle.

Furthermore, in the magnetic sensor system according to one embodiment of the disclosure, the magnetic field generator may be arranged on the side of the second direction with respect to the magnetic sensor. The magnetic field generator may have the first surface located at the end in the second direction, the second surface located at the end in the third direction, the first side surface located at the end in the first direction, the second side surface located at the end in the direction opposite to the first direction, the first connection surface connecting the second surface and the first side surface, and the second connection surface connecting the second surface and the second side surface. The dimension of the first side surface in the second direction and the dimension of the second side surface in the second direction may be smaller than the distance between the first surface and the second surface in the second direction. The dimension of the first connection surface in the second direction may be smaller than the dimension of the first side surface in the second direction. The dimension of the second connection surface in the second direction may be smaller than the dimension of the second side surface in the second direction. The distance between the first connection surface and the first surface in the second direction may become small toward the first side surface. The distance between the second connection surface and the first surface in the second direction may become small toward the second side surface.

Each of the first connection surface and the second connection surface may have a plane. Each of the first connection surface and the second connection surface may have a curved surface. The curved surface may be a protruding surface protruding outward from the magnetic field generator. Alternatively, the curved surface may be a recessed surface recessed toward the inside of the magnetic field generator. The second surface may have a boundary between the first part and the second part.

The second surface may be orthogonal to the second direction. Each of the first connection surface and the second connection surface may be inclined with respect to the imaginary plane orthogonal to the second direction. The magnetic field generated by the magnetic field generator may include the component in the second direction, the component in the third direction, the component perpendicular to the first connection surface, and the component perpendicular to the second connection surface, in the space adjacent to the first part and the second part.

In addition, in the magnetic sensor system according to one embodiment of the disclosure, the magnetic sensor may be configured to detect, among the magnetic field at the detection position, the magnetic field component whose direction changes in the imaginary plane inclined with respect to the first direction, the second direction, and the third direction. The magnetic sensor may include the magnetoresistive element arranged on the slope inclined with respect to the first direction, the second direction, and the third direction.

Furthermore, in the magnetic sensor system according to one embodiment of the disclosure, the magnetic sensor may be configured to detect, among the magnetic field at the detection position, the magnetic field component directed to the second direction or the third direction. The magnetic sensor may include the magnetic field converter that receives the magnetic field component and causes the detection component in the direction parallel to the first direction to be generated, and the magnetoresistive element configured to detect the detection component.

Furthermore, in the magnetic sensor system according to one embodiment of the disclosure, the magnetic sensor may be arranged at a position where, among the magnetic field at the detection position, the magnitude of the first magnetic field component in the direction parallel to the first direction and the magnitude of the second magnetic field component directed to the second direction or the third direction change when the relative position changes, but the magnitude of the third magnetic field component directed to the direction orthogonal to both of the first direction and the second direction does not change. The first magnetic field component may be directed to one direction parallel to the first direction at the center of the variable range of the relative position. The second magnetic field component may be directed to one of the second direction and the third direction at one end of the variable range and directed to the other of the second direction and the third direction at the other end of the variable range.

The position detection device according to one embodiment of the disclosure includes the magnetic sensor system according to one embodiment of the disclosure, and the target object whose position is variable. The magnetic field generator, the magnetic sensor, and the target object are configured such that the relative position changes when the position of the target object changes.

Note that the technology according to the disclosure can be represented as a configuration indicated by the following clauses, for example, but the technology of the disclosure is not limited to them.

Clause 1. A magnetic sensor system comprising:
a magnetic field generator including a first part and a second part aligned in a first direction, the first part being magnetized to include a magnetization component in a second direction orthogonal to the first direction, the second part being magnetized to include a magnetization component in a third direction opposite to the second direction; and
a magnetic sensor configured to detect a magnetic field generated by the magnetic field generator at a detection position, wherein:
the magnetic field generator and the magnetic sensor are configured such that a relative position, which is a relative position of the magnetic field generator with respect to the magnetic sensor, changes in a direction parallel to the first direction;
the magnetic sensor is configured to generate a first detection signal and a second detection signal whose phases differ from each other in response to the relative position, based on the magnetic field;
the first detection signal is a maximum value when the relative position is a first position;
the second detection signal is a maximum value when the relative position is a second position; and
the magnetic field generator is configured such that a distance between the first position and the second position is smaller than a distance between a center of the first part in the first direction and a center of the second part in the first direction.

Clause 2. The magnetic sensor system according to clause 1, wherein a phase difference between the first detection signal and the second detection signal with respect to a change in the relative position is 90° electrical angle.

Clause 3. The magnetic sensor system according to clause 1 or 2, wherein the magnetic field generator is arranged on a side of the second direction with respect to the magnetic sensor.

Clause 4. The magnetic sensor system according to clause 3, wherein:
the magnetic field generator has a first surface located at an end in the second direction, a second surface located at an end in the third direction, a first side surface located at an end in the first direction, a second side surface located at an end in a direction opposite to the first direction, a first connection surface connecting the second surface and the first side surface, and a second connection surface connecting the second surface and the second side surface; and
a dimension of the first side surface in the second direction and a dimension of the second side surface in the second direction are smaller than a distance between the first surface and the second surface in the second direction.

Clause 5. The magnetic sensor system according to clause 4, wherein:
a dimension of the first connection surface in the second direction is smaller than a dimension of the first side surface in the second direction; and
a dimension of the second connection surface in the second direction is smaller than a dimension of the second side surface in the second direction.

Clause 6. The magnetic sensor system according to clause 4 or 5, wherein:
a distance between the first connection surface and the first surface in the second direction becomes small toward the first side surface; and
a distance between the second connection surface and the first surface in the second direction becomes small toward the second side surface.

Clause 7. The magnetic sensor system according to any of clauses 4 to 6, wherein each of the first connection surface and the second connection surface has a plane.

Clause 8. The magnetic sensor system according to any of clauses 4 to 7, wherein each of the first connection surface and the second connection surface has a curved surface.

Clause 9. The magnetic sensor system according to clause 8, wherein the curved surface is a protruding surface protruding outward from the magnetic field generator.

Clause 10. The magnetic sensor system according to clause 8, wherein the curved surface is a recessed surface recessed toward an inside of the magnetic field generator.

Clause 11. The magnetic sensor system according to any of clauses 4 to 10, wherein the second surface has a boundary between the first part and the second part.

Clause 12. The magnetic sensor system according to clause 3, wherein:
the magnetic field generator has a first surface located at an end in the second direction, a second surface located at an end in the third direction, a first side surface located at an end in the first direction, a second side surface located at an end in a direction opposite to the first direction, a first connection surface connecting the second surface and the first side surface, and a second connection surface connecting the second surface and the second side surface;
the second surface is orthogonal to the second direction;
each of the first connection surface and the second connection surface is inclined with respect to an imaginary plane orthogonal to the second direction; and
the magnetic field generated by the magnetic field generator includes a component in the second direction, a component in the third direction, a component perpendicular to the first connection surface, and a component perpendicular to the second connection surface, in a space adjacent to the first part and the second part.

Clause 13. The magnetic sensor system according to any of clauses 1 to 12, wherein the magnetic sensor is configured to detect, among the magnetic field at the detection position, a magnetic field component whose direction changes in an imaginary plane inclined with respect to the first direction, the second direction, and the third direction.

Clause 14. The magnetic sensor system according to clause 13, wherein the magnetic sensor includes a magnetoresistive element arranged on a slope inclined with respect to the first direction, the second direction, and the third direction.

Clause 15. The magnetic sensor system according to any of clauses 1 to 12, wherein the magnetic sensor is configured to detect a magnetic field component, among the magnetic field at the detection position, a magnetic field component directed to the second direction or the third direction.

Clause 16. The magnetic sensor system according to clause 15, wherein the magnetic sensor includes a magnetic field converter that receives the magnetic field component and causes a detection component in a direction parallel to the first direction to be generated, and a magnetoresistive element configured to detect the detection component.

Clause 17. The magnetic sensor system according to any of clauses 1 to 16, wherein the magnetic sensor is arranged at a position where, among the magnetic field at the detection position, a magnitude of a first magnetic field component in a direction parallel to the first direction and a magnitude of a second magnetic field component directed to the second direction or the third direction change when the relative position changes, and a magnitude of a third magnetic field component directed to a direction orthogonal to both of the first direction and the second direction does not change.

Clause 18. The magnetic sensor system according to clause 17, wherein:
the first magnetic field component is directed to one direction parallel to the first direction at a center of a variable range of the relative position; and
the second magnetic field component is directed to one of the second direction and the third direction at one end of the variable range and directed to another of the second direction and the third direction at another end of the variable range.

Clause 19. A position detection device including:
the magnetic sensor system according to any of clauses 1 to 18; and
a target object whose position is variable, wherein
the magnetic field generator, the magnetic sensor, and the target object are configured such that the relative position changes when a position of the target object changes.

Based on the foregoing description, it is clear that the various embodiments and the modification examples of the disclosure can be implemented. Therefore, the disclosure can be implemented in forms other than the above-described example embodiments, within the scope of the equivalents of the appended claims.

1. A magnetic sensor system comprising:
a magnetic field generator including a first part and a second part aligned in a first direction, the first part being magnetized to include a magnetization component in a second direction orthogonal to the first direction, the second part being magnetized to include a magnetization component in a third direction opposite to the second direction; and
a magnetic sensor configured to detect a magnetic field generated by the magnetic field generator at a detection position, wherein:
the magnetic field generator and the magnetic sensor are configured such that a relative position, which is a relative position of the magnetic field generator with respect to the magnetic sensor, changes in a direction parallel to the first direction;
the magnetic sensor is configured to generate a first detection signal and a second detection signal whose phases differ from each other in response to the relative position, based on the magnetic field;
the first detection signal is a maximum value when the relative position is a first position;
the second detection signal is a maximum value when the relative position is a second position; and
the magnetic field generator is configured such that a distance between the first position and the second position is smaller than a distance between a center of the first part in the first direction and a center of the second part in the first direction.

2. The magnetic sensor system according to claim 1, wherein a phase difference between the first detection signal and the second detection signal with respect to a change in the relative position is 90° electrical angle.

3. The magnetic sensor system according to claim 1, wherein the magnetic field generator is arranged on a side of the second direction with respect to the magnetic sensor.

4. The magnetic sensor system according to claim 3, wherein:
the magnetic field generator has a first surface located at an end in the second direction, a second surface located at an end in the third direction, a first side surface located at an end in the first direction, a second side surface located at an end in a direction opposite to the first direction, a first connection surface connecting the second surface and the first side surface, and a second connection surface connecting the second surface and the second side surface; and
a dimension of the first side surface in the second direction and a dimension of the second side surface in the second direction are smaller than a distance between the first surface and the second surface in the second direction.

5. The magnetic sensor system according to claim 4, wherein:
a dimension of the first connection surface in the second direction is smaller than a dimension of the first side surface in the second direction; and
a dimension of the second connection surface in the second direction is smaller than a dimension of the second side surface in the second direction.

6. The magnetic sensor system according to claim 4, wherein:
a distance between the first connection surface and the first surface in the second direction becomes small toward the first side surface; and
a distance between the second connection surface and the first surface in the second direction becomes small toward the second side surface.

7. The magnetic sensor system according to claim 6, wherein each of the first connection surface and the second connection surface has a plane.

8. The magnetic sensor system according to claim 6, wherein each of the first connection surface and the second connection surface has a curved surface.

9. The magnetic sensor system according to claim 8, wherein the curved surface is a protruding surface protruding outward from the magnetic field generator.

10. The magnetic sensor system according to claim 8, wherein the curved surface is a recessed surface recessed toward an inside of the magnetic field generator.

11. The magnetic sensor system according to claim 4, wherein the second surface has a boundary between the first part and the second part.

12. The magnetic sensor system according to claim 3, wherein:
the magnetic field generator has a first surface located at an end in the second direction, a second surface located at an end in the third direction, a first side surface located at an end in the first direction, a second side surface located at an end in a direction opposite to the first direction, a first connection surface connecting the second surface and the first side surface, and a second connection surface connecting the second surface and the second side surface;
the second surface is orthogonal to the second direction;
each of the first connection surface and the second connection surface is inclined with respect to an imaginary plane orthogonal to the second direction; and
the magnetic field generated by the magnetic field generator includes a component in the second direction, a component in the third direction, a component perpendicular to the first connection surface, and a component perpendicular to the second connection surface, in a space adjacent to the first part and the second part.

13. The magnetic sensor system according to claim 1, wherein the magnetic sensor is configured to detect, among the magnetic field at the detection position, a magnetic field component whose direction changes in an imaginary plane inclined with respect to the first direction, the second direction, and the third direction.

14. The magnetic sensor system according to claim 13, wherein the magnetic sensor includes a magnetoresistive element arranged on a slope inclined with respect to the first direction, the second direction, and the third direction.

15. The magnetic sensor system according to claim 1, wherein the magnetic sensor is configured to detect a magnetic field component, among the magnetic field at the detection position, a magnetic field component directed to the second direction or the third direction.

16. The magnetic sensor system according to claim 15, wherein the magnetic sensor includes a magnetic field converter that receives the magnetic field component and causes a detection component in a direction parallel to the first direction to be generated, and a magnetoresistive element configured to detect the detection component.

17. The magnetic sensor system according to claim 1, wherein the magnetic sensor is arranged at a position where, among the magnetic field at the detection position, a magnitude of a first magnetic field component in a direction parallel to the first direction and a magnitude of a second magnetic field component directed to the second direction or the third direction change when the relative position changes, and a magnitude of a third magnetic field component directed to a direction orthogonal to both of the first direction and the second direction does not change.

18. The magnetic sensor system according to claim 17, wherein:
the first magnetic field component is directed to one direction parallel to the first direction at a center of a variable range of the relative position; and
the second magnetic field component is directed to one of the second direction and the third direction at one end of the variable range and directed to another of the second direction and the third direction at another end of the variable range.

19. A position detection device comprising:
the magnetic sensor system according to claim 1; and
a target object whose position is variable, wherein
the magnetic field generator, the magnetic sensor, and the target object are configured such that the relative position changes when a position of the target object changes.
